(19) United States
(12) Patent Application Publication
(10) Pub. No.: US 2025/0174534 A1
(43) Pub. Date: May 29, 2025

(54) SEMICONDUCTOR PACKAGES AND METHODS OF MANUFACTURING THE SAME

(71) Applicant: Samsung Electronics Co., Ltd., Suwon-si (KR)

(72) Inventors: Jinwoo Park, Suwon-si (KR); Unbyoung Kang, Suwon-si (KR)

(21) Appl. No.: 18/740,590

(22) Filed: Jun. 12, 2024

(30) Foreign Application Priority Data
Nov. 28, 2023 (KR) 10-2023-0168232

(51) Int. Cl. H01L 23/498; H01L 23/00; H01L 23/538; H01L 25/065

(52) U.S. Cl. CPC H01L 23/49822; H01L 23/49827; H01L 23/49838; H01L 23/5384; H01L 23/5386; H01L 24/24; H01L 25/0655; H01L 2224/24137; H01L 2224/24226; H01L 2224/244

(57) ABSTRACT

A semiconductor package including a redistribution layer, a first lower post on the redistribution layer, a second lower post on the redistribution layer and spaced laterally apart from the first lower post, a first upper connection post on the first lower post, a second upper connection post on the second lower post, a bridge structure between the first lower post and the second lower post, a semiconductor device on the first upper connection post and a first area of the bridge structure, a semiconductor chip on the second upper connection post and a second area of the bridge structure and spaced laterally apart from the semiconductor device, and a lower molding layer provided on the redistribution layer and covering sidewalls of the first and second lower posts and sidewalls of the first and second upper connection posts.

### CROSS-REFERENCE TO RELATED APPLICATION

This application is based on and claims priority under 35 U.S.C. § 119 to Korean Patent Application No. 10-2023-0168232, filed on Nov. 28, 2023, in the Korean Intellectual Property Office, and the entire contents of the above-identified application are incorporated by reference herein in its entirety.

### BACKGROUND

The present disclosure relates to semiconductor packages, and more particularly, to semiconductor packages including redistribution layers and methods of manufacturing the semiconductor packages.

Semiconductor packages are integrated circuit chips that are implemented in a form suitable for use in electronic products. Typically, semiconductor packages may include a semiconductor chip mounted on a printed circuit board. The semiconductor chip may be electrically connected to the printed circuit board by bonding wires or bumps. With the recent development of the electronics industry, there is an increasing demand for improving reliability of semiconductor packages.

### SUMMARY

The inventive concepts provide semiconductor packages with improved reliability and methods of manufacturing the semiconductor packages.

The inventive concepts also provide semiconductor packages with improved accuracy and efficiency and methods of manufacturing the semiconductor packages.

According to some aspects of the inventive concepts, there is provided a semiconductor package including a redistribution layer, a first lower post on the redistribution layer, a second lower post on the redistribution layer and spaced laterally apart from the first lower post, a first upper connection post on the first lower post, a second upper connection post on the second lower post, a bridge structure on the redistribution layer and between the first lower post and the second lower post, a semiconductor device on the first upper connection post and a first area of the bridge structure, a semiconductor chip on the second upper connection post and a second area of the bridge structure and laterally apart from the semiconductor device, and a lower molding layer on the redistribution layer and covering sidewalls of the first and second lower posts and sidewalls of the first and second upper connection posts. The lower molding layer may be in direct contact with a bottom surface of the semiconductor device and a bottom surface of the semiconductor chip.

According to some aspects of the inventive concepts, there is provided a semiconductor package including a first semiconductor chip, a second semiconductor chip spaced laterally apart from the first semiconductor chip, a first upper connection post on a bottom surface of the first semiconductor chip and connected to the first semiconductor chip, a second upper connection post on a bottom surface of the second semiconductor chip and connected to the second semiconductor chip, a first lower post on a bottom surface of the first upper connection post, a second lower post on a bottom surface of the second upper connection post, a bridge structure on the bottom surface of the first semiconductor chip and the bottom surface of the second semiconductor chip and spaced laterally apart from the first and second lower posts, a first molding layer covering sidewalls of the first and second semiconductor chips and spaced apart from the first and second upper connection posts, and a second molding layer on a bottom surface of the first molding layer. The second molding layer may cover the bridge structure, sidewalls of the first and second lower posts, and sidewalls of the first and second upper connection posts.

According to some aspects of the inventive concepts, there is provided a semiconductor package including a package substrate including lower substrate pads, substrate wires, and upper substrate pads, solder ball terminals on bottom surfaces of the lower substrate pads, a redistribution layer on a top surface of the package substrate and including an insulating layer, redistribution patterns, seed patterns, and redistribution pads, connection solder balls between the package substrate and the redistribution layer and connected to the upper substrate pads and the redistribution pads, lower posts on a top surface of the redistribution layer and electrically connected to the redistribution patterns, the lower posts including a first lower post and a second lower post laterally apart from each other, a first upper connection post on the first lower post, a second upper connection post on the second lower post, a bridge structure on the top surface of the redistribution layer and between the first lower post and the second lower post, a chip stack package on a top surface of the first upper connection post and a first area of the bridge structure and connected to the first upper connection post and the bridge structure, the chip stack package including a first lower semiconductor chip, a second semiconductor chip on a top surface of the second upper connection post and a second area of the bridge structure and connected to the second upper connection post and the bridge structure, the second semiconductor chip being laterally apart from the chip stack package, a first molding layer covering a sidewall of the chip stack package and a sidewall of the second semiconductor chip, and a second molding layer on the top surface of the redistribution layer and covering sidewalls of the first and second lower posts and sidewalls of the first and second upper connection posts. The second molding layer may be in direct contact with a bottom surface of the first molding layer, a bottom surface of the chip stack package, and a bottom surface of the second semiconductor chip.

According to some aspects of the inventive concepts, there is provided a method of manufacturing a semiconductor package, the method including preparing a semiconductor device having a bottom surface on which a first upper post is provided, preparing a semiconductor chip having a bottom surface on which a second upper post is provided, attaching the semiconductor device and the semiconductor chip to a carrier substrate by using a carrier adhesive layer, the first upper post and the second upper post in the carrier adhesive layer, forming a first molding layer on the carrier adhesive layer that covers the semiconductor device and the semiconductor chip, and exposing a bottom surface of the first molding layer, a bottom surface of the semiconductor device, a bottom surface of the semiconductor chip, and the first and second upper posts by removing the carrier adhesive layer and the carrier substrate. The bottom surface of the first molding layer may be at a higher level than a bottom surface of the first upper post and a bottom surface of the second upper post.

### BRIEF DESCRIPTION OF THE DRAWINGS

Embodiments will be more clearly understood from the following detailed description taken in conjunction with the accompanying drawings in which:

FIG. 1A is a cross-sectional view illustrating a semiconductor package according to some embodiments;

FIG. 1B is a cross-sectional view taken along line I-I′ of FIG. 1A;

FIG. 1C is an enlarged view of region II of FIG. 1B;

FIG. 1D is a diagram for describing a semiconductor package according to some embodiments and corresponds to an enlarged view of region II of FIG. 1B;

FIG. 2A is a cross-sectional view for describing a semiconductor package according to some embodiments;

FIG. 2B is an enlarged view of region II of FIG. 1B;

FIG. 3A is a diagram for describing a first upper connection post and a first lower post according to some embodiments;

FIG. 3B is a diagram for describing a second upper connection post and a second lower post according to some embodiments;

FIG. 3C is a diagram for describing a first upper connection post and a first lower post according to some embodiments;

FIG. 3D is a diagram for describing a second upper connection post and a second lower post according to some embodiments;

FIG. 3E is a diagram for describing a first upper connection post and a first lower post according to some embodiments;

FIG. 3F is a diagram for describing a second upper connection post and a second lower post according to some embodiments;

FIG. 3G is a diagram for describing a first upper connection post and a first lower post according to some embodiments;

FIG. 3H is a diagram for describing a second upper connection post and a second lower post according to some embodiments;

FIG. 4 is a cross-sectional view for describing a semiconductor package according to some embodiments;

FIG. 5A is a diagram for describing a first upper connection post and a first upper bridge post according to some embodiments;

FIG. 5B is a diagram for describing a first upper connection post and a first upper bridge post according to some embodiments;

FIG. 5C is a diagram for describing a first upper connection post and a first upper bridge post according to some embodiments;

FIG. 5D is a diagram for describing a second upper connection post and a second upper bridge post according to some embodiments;

FIG. 5E is a diagram for describing a second upper connection post and a second upper bridge post according to some embodiments;

FIG. 5F is a diagram for describing a second upper connection post and a second upper bridge post according to some embodiments;

FIG. 6 is a cross-sectional view for describing a semiconductor device according to some embodiments; and

FIGS. 7A to 7K are diagrams for describing a process of manufacturing a semiconductor package, according to some embodiments.

### DETAILED DESCRIPTION OF THE EMBODIMENTS

Like reference numerals may denote like elements throughout the specification. A semiconductor package and a method of manufacturing the same, according to the inventive concepts of the present disclosure, will be described.

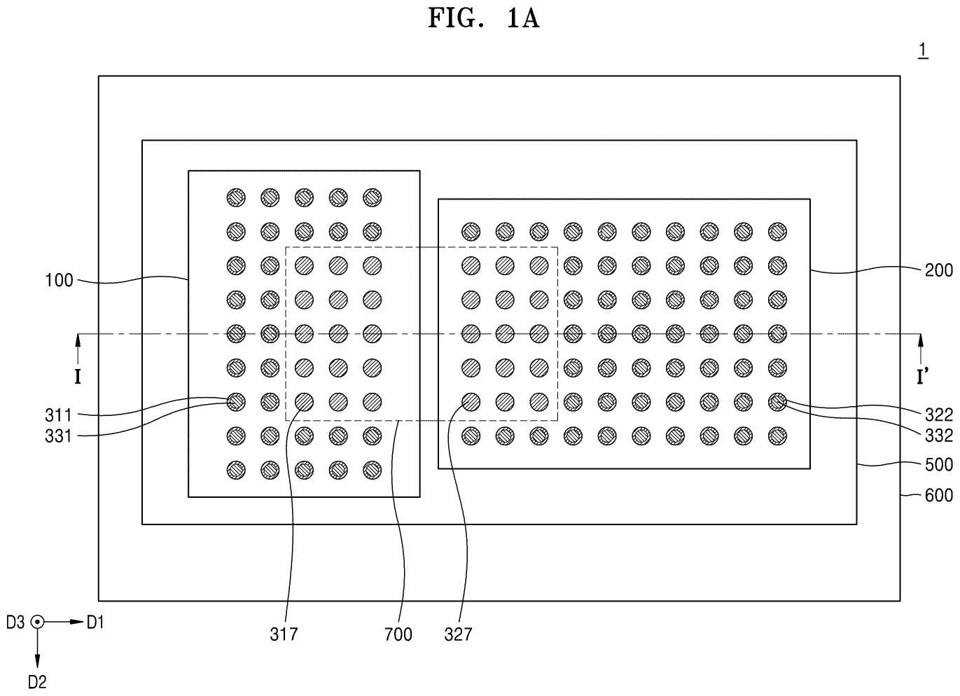

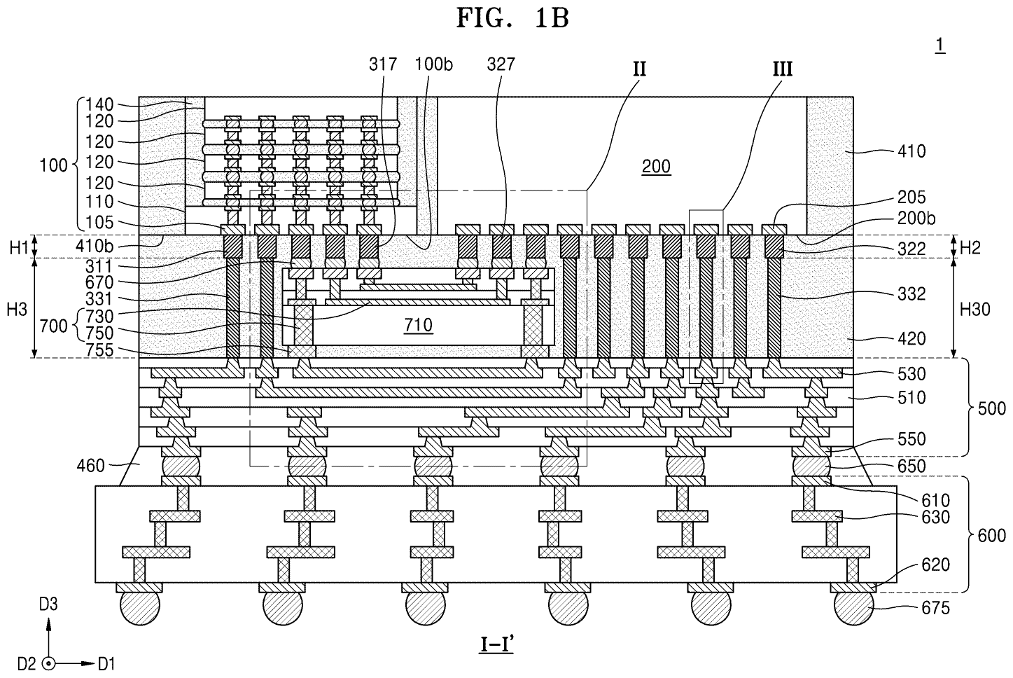

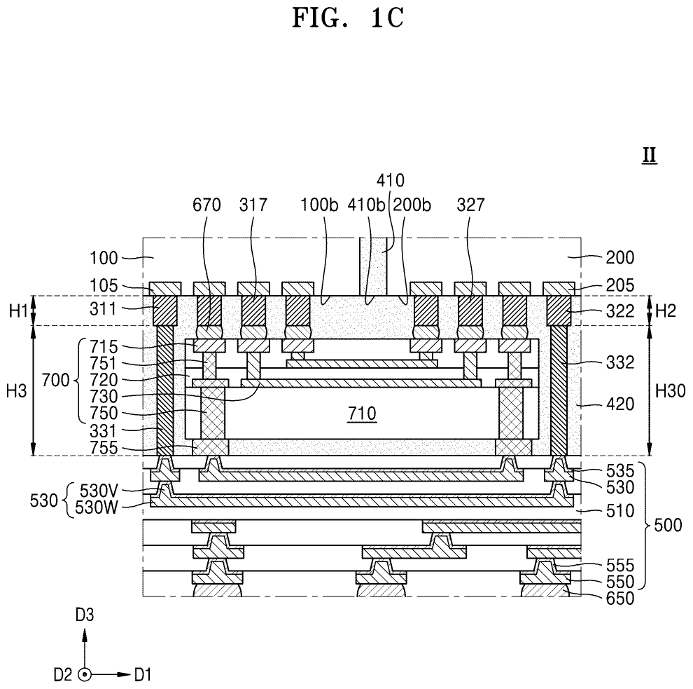

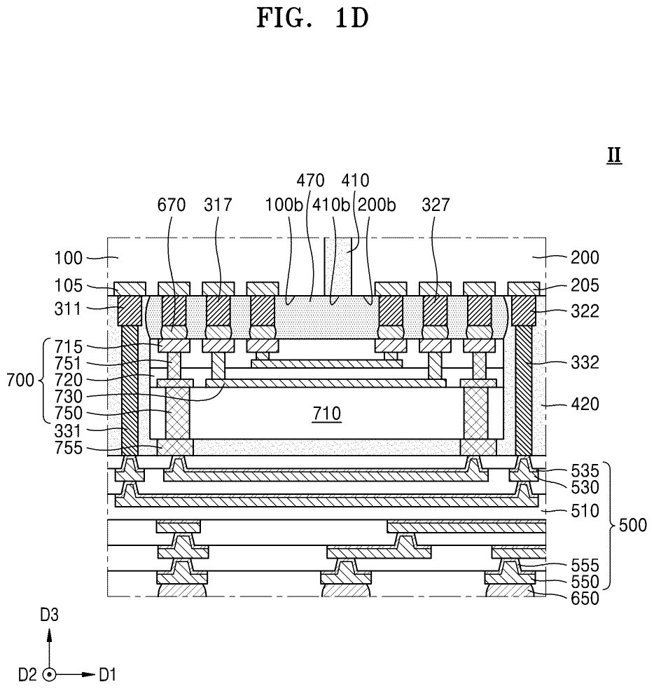

FIG. 1A is a cross-sectional view illustrating a semiconductor package 1 according to some embodiments. FIG. 1B is a cross-sectional view taken along line I-I′ of FIG. 1A. FIG. 1C is an enlarged view of region II of FIG. 1B.

Referring to FIGS. 1A to 1C, the semiconductor package 1 may include a package substrate 600, solder ball terminals 675, a redistribution layer 500, a first lower post 331, a second lower post 332, a bridge structure 700, first upper posts 311 and 317, second upper posts 322 and 327, a semiconductor device 100 including a first lower semiconductor chip 110, a second semiconductor chip 200, a first molding layer 410, and a second molding layer 420.

The package substrate 600 may include lower substrate pads 620, substrate wires 630, and upper substrate pads 610. For example, a printed circuit board may be used as the package substrate 600. The upper substrate pads 610 and the lower substrate pads 620 may be respectively provided on the top surface and the bottom surface of the package substrate 600. The substrate wires 630 may be provided in the package substrate 600 and may be connected to the lower substrate pads 620 and the upper substrate pads 610. Accordingly, the lower substrate pads 620 may be respectively connected to the upper substrate pads 610 through the substrate wires 630. Herein, the expression “being electrically connected to the package substrate 600” may mean “being electrically connected to at least one of the substrate wires 630.” An electrical connection between two components may include a direct connection or an indirect connection through other components. The lower substrate pads 620, the substrate wires 630, and the upper substrate pads 610 may each include a metal, such as copper, aluminum, tungsten, and/or titanium.

A first direction D1 may be parallel to the top surface of the package substrate 600. A second direction D2 may be parallel to the top surface of the package substrate 600 and may cross the first direction D1. For example, the second direction D2 may be perpendicular to the first direction D1. A third direction D3 may be perpendicular to the top surface of the package substrate 600. The third direction D3 may be a vertical direction. Herein, the term “vertical” may mean parallel to the third direction D3. The third direction D3 may be perpendicular to the first direction D1 and the second direction D2.

The solder ball terminals 675 may be provided on the bottom surface of the package substrate 600 and each may be electrically connected to a respective one of the lower substrate pads 620. Electrical signals (e.g., external electrical signals) may be transmitted to and from the package substrate 600 (and to and from other components of the semiconductor package 1) through the solder ball terminals 675. The solder ball terminals 675 may each include a solder material. The solder material may include, for example, tin, silver, bismuth, or any alloy thereof.

The redistribution layer 500 may be on the package substrate 600. The redistribution layer 500 may include an insulating layer 510, redistribution patterns 530, and redistribution pads 550. Herein, the expression “being electrically connected to the redistribution layer 500” may mean “being electrically connected to one of the redistribution patterns 530.” The redistribution layer 500 may include a plurality of insulating layers 510. The insulating layers 510 may be vertically stacked. The number of stacked insulating layers 510 may vary. As an example, the insulating layers 510 may include the same material. Interfaces between insulating layers 510 adjacent to each other may not be distinguished. Each insulating layer 510 may include an organic material, such as a photo-imageable dielectric (PID) material. The PID material may include, for example, at least one of photosensitive polyimide (PSPI), polybenzoxazole, phenol-based polymer, and benzocyclobutene-based polymer.

The redistribution patterns 530 may be provided between the insulating layers 510 and may further extend on and/or in the insulating layers 510. Some redistribution patterns 530 may be vertically stacked and may be electrically connected to each other. The redistribution patterns 530 may include a metal, such as copper and/or a copper alloy.

The redistribution pads 550 may be provided on the bottom surface of the redistribution layer 500 and may be electrically connected to the redistribution patterns 530. The redistribution pads 550 may be spaced laterally apart from each other.

The semiconductor package 1 may further include connection solder balls 650. The connection solder balls 650 may be provided between the package substrate 600 and the redistribution layer 500 and may be respectively connected to the upper substrate pads 610 and the redistribution pads 550. The connection solder balls 650 may each include a solder material. The redistribution layer 500 may be electrically connected to the solder ball terminals 675 through the connection solder balls 650 and the package substrate 600.

The semiconductor device 100 may be on the redistribution layer 500. The semiconductor device 100 may include a chip stack package. For example, the chip stack package may include a first lower semiconductor chip 110 and one or more first upper semiconductor chips 120. The first upper semiconductor chips 120 may be vertically stacked on the first lower semiconductor chip 110. The first lower semiconductor chip 110 may be a logic chip or a controller chip. Herein, the expression “being electrically connected to the semiconductor device 100” may include “being electrically connected to the first lower semiconductor chip 110.” The first upper semiconductor chips 120 may be memory chips. Each memory chip of the first upper semiconductor chips 120 may include a high bandwidth memory (HBM) chip. The chip stack package may be an HBM package. The number of first upper semiconductor chips 120 is not limited to that illustrated in FIG. 1B and may vary. For example, the semiconductor device 100 may include a single first upper semiconductor chip 120 or five or more first upper semiconductor chips 120. The semiconductor device 100 may further include an inner molding layer 140. The inner molding layer 140 may be on the top surface of the first lower semiconductor chip 110 and may cover sidewalls of the first upper semiconductor chip 120.

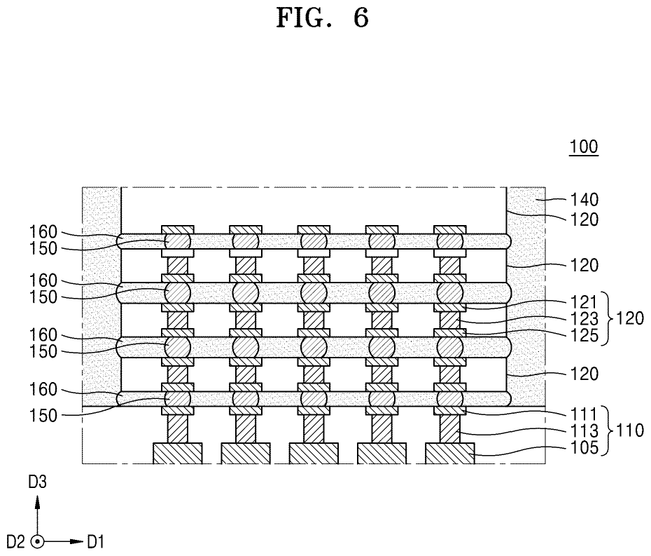

Sidewalls of the semiconductor device 100 may include sidewalls of the first lower semiconductor chip 110 and sidewalls of the inner molding layer 140. A bottom surface 100b of the semiconductor device 100 may correspond to the bottom surface of the first lower semiconductor chip 110. The first lower semiconductor chip 110 may include first lower pads 105. The first lower pads 105 may be provided on the bottom surface of the first lower semiconductor chip 110. In the present specification, the first lower pads 105 of the semiconductor device 100 may correspond to the first lower pads 105 of the first lower semiconductor chip 110. In the present specification, a first semiconductor chip may refer to the first lower semiconductor chip 110. Specific examples of the semiconductor device 100 are described below with reference to FIG. 6. Hereinafter, in the drawings except for FIGS. 1B and 6, the components of the semiconductor device 100 except for the first lower pads 105 may be omitted for simplicity.

The second semiconductor chip 200 may be provided on the redistribution layer 500 and may be spaced laterally apart from the semiconductor device 100. For example, the second semiconductor chip 200 may be spaced laterally apart from the first lower semiconductor chip 110. Herein, the expression “two components are spaced laterally apart from each other” may mean that two components are horizontally spaced apart from each other and are not directly contacting one another. Herein, the term “horizontal” may mean “parallel to the top surface of the package substrate 600.” For example, the second semiconductor chip 200 may be spaced apart from the first lower semiconductor chip 110 in the first direction D1 or in a direction opposite to the first direction D1.

The second semiconductor chip 200 may be a different type of device from the semiconductor device 100. For example, the function of the second semiconductor chip 200 may be different from the function of the first lower semiconductor chip 110 and the function of the first upper semiconductor chip 120. The second semiconductor chip 200 may be a logic chip. The second semiconductor chip 200 may be a different type of logic chip from the first lower semiconductor chip 110. For example, the second semiconductor chip 200 may include a graphics processing unit (GPU) or a central processing unit (CPU). The second semiconductor chip 200 may include integrated circuits and chip pads 205. The integrated circuits may be provided in the second semiconductor chip 200 and may be adjacent to a bottom surface 200b of the second semiconductor chip 200. The chip pads 205 may be on the bottom surface 200b of the second semiconductor chip 200 and may be respectively electrically connected to the integrated circuits. Herein, the expression “being electrically connected to the second semiconductor chip 200” may mean “being electrically connected to the integrated circuits through chip pads 205.”

The first molding layer 410 may cover the sidewalls of the semiconductor device 100 and the sidewalls of the second semiconductor chip 200. For example, the first molding layer 410 may cover the sidewalls of the first lower semiconductor chip 110 and the sidewalls of the second semiconductor chip 200. A bottom surface 410b of the first molding layer 410 may be coplanar with the bottom surface 100b of the semiconductor device 100 and the bottom surface 200b of the second semiconductor chip 200. For example, the bottom surface 410b of the first molding layer 410 may be at substantially the same level as (e.g., coplanar with) the bottom surface 100b of the semiconductor device 100 and the bottom surface 200b of the second semiconductor chip 200. A level of a certain component may refer to a vertical level or a level parallel to the third direction D3. The level difference between two components may be measured in a direction parallel to the third direction D3. Herein, the expression “the widths, heights, and levels of certain components are the same” may be inclusive of a sameness and/or values thereof falling within an error range that may occur during manufacturing and/or forming processes. The first molding layer 410 may expose the top surface of the semiconductor device 100 and the top surface of the second semiconductor chip 200. In another embodiment, the first molding layer 410 may further cover the top surface of the semiconductor device 100 and the top surface of the second semiconductor chip 200. The first molding layer 410 may include an insulating polymer, such as an epoxy-based molding compound (EMC).

The first upper posts 311 and 317 may be on the bottom surface 100b of the semiconductor device 100 and may be electrically connected to the semiconductor device 100. For example, the first upper posts 311 and 317 may be provided on the bottom surfaces of the first lower pads 105 and may be connected to the first lower pads 105. The first upper posts 311 and 317 may include the same material. The first upper posts 311 and 317 may each include a metal material, such as copper. The first upper posts 311 and 317 may each further include nickel or gold (Au), but the present disclosure is not limited thereto.

The first upper posts 311 and 317 may include a first upper connection post 311 and a first upper bridge post 317. The height H1 of the first upper connection post 311 may be, for example, about 5 μm to about 10 μm. Because the height H1 of the first upper connection post 311 is 10 μm or less, the semiconductor package 1 may be miniaturized. The first upper bridge post 317 may be spaced laterally apart from the first upper connection post 311. The first upper bridge post 317 may be adjacent to the second semiconductor chip 200 in a plan view. The height of the first upper bridge post 317 may be substantially equal to the height H1 of the first upper connection post 311. The height of the first upper bridge post 317 may be, for example, about 5 μm to about 10 μm.

Second upper posts 322 and 327 may be on the bottom surface 200b of the second semiconductor chip 200 and may be electrically connected to the second semiconductor chip 200. For example, the second upper posts 322 and 327 may be provided on the bottom surfaces of the chip pads 205 of the second semiconductor chip 200 and may be connected to the chip pads 205. The second upper posts 322 and 327 may include the same material. The second upper posts 322 and 327 may each include a metal material, such as copper. As an example, the second upper posts 322 and 327 may each further include nickel or Au. The second upper posts 322 and 327 may include the same metal as the first upper posts 311 and 317. As another example, the second upper posts 322 and 327 may include different metals than the first upper posts 311 and 317.

The second upper posts 322 and 327 may include a second upper connection post 322 and a second upper bridge post 327. The height H2 of the second upper connection post 322 may be different from the height H1 of the first upper connection post 311. In this case, the height H2 of the second upper connection post 322 may be different from the height of the first upper bridge post 317. Alternatively, the height H2 of the second upper connection post 322 may be equal to or similar to the height H1 of the first upper connection post 311 and the height of the first upper bridge post 317. The height H2 of the second upper connection post 322 may be, for example, about 5 μm to about 10 μm. Because the height H2 of the second upper connection post 322 is 10 m or less, the semiconductor package 1 may be miniaturized.

The second upper bridge post 327 may be spaced laterally apart from the second upper connection post 322. The height of the second upper bridge post 327 may be substantially equal to the height H2 of the second upper connection post 322. The height of the second upper bridge post 327 may be different from the height H1 of the first upper connection post 311 and the height of the first upper bridge post 317. Alternatively, the height of the second upper bridge post 327 may be equal to or similar to the height H1 of the first upper connection post 311 and the height of the first upper bridge post 317. The height of the second upper bridge post 327 may be, for example, about 5 μm to about 10 μm.

The first and second lower posts 331 and 332 may be provided on the top surface of the redistribution layer 500 and may be electrically connected to the redistribution patterns 530. The first and second lower posts 331 and 332 may be spaced laterally apart from each other. The first and second lower posts 331 and 332 may each include copper, titanium, and/or any alloy thereof.

The first and second lower posts 331 and 332 may include a first lower post 331 and a second lower post 332. The first lower post 331 may be between the redistribution layer 500 and the first upper connection post 311 and may be connected to the first upper connection post 311. The first lower post 331 may vertically overlap the semiconductor device 100. The semiconductor device 100 may be electrically connected to the redistribution layer 500 through the first upper connection post 311 and the first lower post 331. The first lower post 331 may include the same metal as the first upper posts 311 and 317. For example, the first lower post 331 may include copper or a copper alloy. The height H3 of the first lower post 331 may be greater than the height H1 of the first upper connection post 311 and the height H2 of the second upper connection post 322. For example, the height H3 of the first lower post 331 may be, for example, about 30 μm to about 50 μm. Because the height H3 of the first lower post 331 is 50 μm or less, the semiconductor package 1 may be miniaturized.

The second lower post 332 may be spaced laterally apart from the first lower post 331. The second lower post 332 may be provided between the redistribution layer 500 and the second upper connection post 322 and may be connected to the redistribution layer 500 and the second upper connection post 322. The second lower post 332 may vertically overlap the second semiconductor chip 200. The second semiconductor chip 200 may be electrically connected to the redistribution layer 500 through the second lower post 332 and the second upper connection post 322.

The second lower post 332 may include the same metal as the second upper connection post 322 and the second upper bridge post 327. The second lower post 332 may include the same metal as the first lower post 331. For example, the second lower post 332 may include copper or a copper alloy.

The semiconductor package 1 may include a plurality of first lower posts 331, a plurality of second lower posts 332, a plurality of first upper connection posts 311, and a plurality of second upper connection posts 322. The first upper connection posts 311 may be respectively connected to the first lower posts 331. The second upper connection posts 322 may be respectively connected to the second lower posts 332.

One of the second lower posts 332 may be electrically connected to one of the first lower posts 331 through the redistribution pattern 530. Thus, the second semiconductor chip 200 may be electrically connected to the semiconductor device 100 through the one second lower post 332, the one redistribution pattern 530, and the one first lower post 331. Therefore, the length of the electrical path between the semiconductor device 100 and the second semiconductor chip 200 may be reduced.

The semiconductor device 100 may be electrically connected to the package substrate 600 through another first lower post 331 and another redistribution pattern 530. The second semiconductor chip 200 may be electrically connected to the package substrate 600 through another second lower post 332 and another redistribution pattern 530. For simplicity, a single first lower post 331, a single first upper connection post 311, a single second lower post 332, and a single second upper connection post 322 have been or are described.

The bridge structure 700 may be on the top surface of the redistribution layer 500. The bridge structure 700 may be between the first lower post 331 and the second lower post 332. The bridge structure 700 may be spaced laterally apart from the first lower post 331 and the second lower post 332.

The bridge structure 700 may have a first area and a second area when viewed in a plan view. The semiconductor device 100 and the second semiconductor chip 200 may be provided on the bridge structure 700. For example, the semiconductor device 100 may be provided on the top surface of the bridge structure 700 in the first area. The second semiconductor chip 200 may be provided on the top surface of the bridge structure 700 in the second area.

The bridge structure 700 may include a base substrate 710, bridge wires 730, and through-vias 750. The bridge wires 730 may be provided in the bridge structure 700. The bridge wires 730 may be provided on the base substrate 710 and may extend horizontally. For example, at least one of the bridge wires 730 may extend in a direction parallel to the first direction D1. The second semiconductor chip 200 may be electrically connected to the semiconductor device 100 through the bridge wires 730. The bridge wires 730 may be spaced apart from each other and insulated from each other. According to some embodiments, because the bridge structure 700 is provided, the length of the electrical path between the semiconductor device 100 and the second semiconductor chip 200 may be further reduced. Accordingly, the performance of the semiconductor package 1 may be improved. In the present specification, vias may be configured for vertical connection and wires may be configured for horizontal connection.

The through-vias 750 may be provided in the bridge structure 700. The through-vias 750 may vertically penetrate through the base substrate 710. The through-vias 750 may be spaced apart from the bridge wires 730 and insulated from the bridge wires 730. When the number of bridge wires 730 increases beyond a certain number, the bridge wires 730 may be difficult to design and manufacture. According to some embodiments, the semiconductor device 100 may be electrically connected to one of the redistribution patterns 530 through one of the through-vias 750. The second semiconductor chip 200 may be electrically connected to one of the redistribution patterns 530 through another of the through-vias 750. The second semiconductor chip 200 may be electrically connected to the same one of the redistribution patterns 530 that is electrically connected to the first semiconductor chip 100. The second semiconductor chip 200 may be electrically connected to the semiconductor device 100 through the at least two through-vias 750 and the one redistribution pattern 530. Accordingly, the length of the electrical path between the semiconductor device 100 and the second semiconductor chip 200 may be reduced. The second semiconductor chip 200 may be electrically connected to the semiconductor device 100 through the through-vias 750 as well as the bridge wires 730. According to some embodiments, even when the number of electrical paths between the semiconductor device 100 and the second semiconductor chip 200 increases, signals may be relatively quickly transmitted between the semiconductor device 100 and the second semiconductor chip 200. Accordingly, the semiconductor package 1 may have improved performance and may be miniaturized.

The bottom surface of the first lower post 331 and the bottom surface of the second lower post 332 may be provided at a lower level than the bottom surface of the bridge structure 700. Because the height H3 of the first lower post 331 and the height H30 of the second lower post 332 are each 30 μm or more, the bridge structure 700 may be between the first lower post 331 and the second lower post 332. When the height H3 of the first lower post 331 and the height H30 of the second lower post 332 satisfy the above conditions, the semiconductor device 100 and the second semiconductor chip 200 may be electrically connected to each other through the bridge structure 700.

The second molding layer 420 may be provided between the top surface of the redistribution layer 500 and the bottom surface 410b of the first molding layer 410. The second molding layer 420 may cover the sidewalls of the first and second lower posts 331 and 332, the sidewalls of the first upper posts 311 and 317, and the sidewalls of the second upper posts 322 and 327. The second molding layer 420 may further cover the bridge structure 700. The second molding layer 420 may further extend to a gap area between the bridge structure 700 and the semiconductor device 100, a gap area between the bridge structure 700 and the first molding layer 410, and a gap area between the bridge structure 700 and the second semiconductor chip 200 and may cover the sidewalls of the first and second upper bridge posts 317 and 327. The second molding layer 420 may protect the first and second lower posts 331 and 332, the first upper posts 311 and 317, the second upper posts 322 and 327, and the bridge structure 700. The second molding layer 420 may be in physical contact with the bottom surface 410b of the first molding layer 410, the bottom surface 100b of the semiconductor device 100, and the bottom surface 200b of the second semiconductor chip 200. That is, the semiconductor device 100 and the second semiconductor chip 200 may be directly on the top surface of the second molding layer 420.

According to some embodiments, the second molding layer 420 may include the same material as the first molding layer 410. For example, the second molding layer 420 may include the same EMC as the first molding layer 410. For example, the composition ratio of the EMC included in the second molding layer 420 may be substantially equal to the composition ratio of the EMC included in the second molding layer 420. The coefficient of thermal expansion (CTE) of the second molding layer 420 may be substantially equal to the CTE of the first molding layer 410. When the semiconductor package 1 operates, the temperature of the semiconductor package 1 may change. When the CTEs of two components are different, warpage of the semiconductor package 1 may occur due to the difference in CTEs between the components. For example, warpage of the two components or other components adjacent to the two components may occur. According to embodiments, because the CTE of the second molding layer 420 is substantially equal to the CTE of the first molding layer 410, warpage of the semiconductor package 1 may be prevented. Accordingly, the semiconductor package 1 may have improved operational reliability and thermal characteristics.

Hereinafter, the redistribution layer 500 and the bridge structure 700 are described in more detail with reference to FIG. 1C. Also, some descriptions redundant with those provided above may be omitted in the interest of brevity.

Referring to FIGS. 1B and 1C together, the redistribution layer 500 may be manufactured by a chip first process. Each of the redistribution patterns 530 may include a via portion 530V and a wire portion 530W. The wire portion 530W of each of the redistribution patterns 530 may be provided between the insulating layers 510. The via portion 530V of each of the redistribution patterns 530 may be provided in the corresponding insulating layer 510. The via portion 530V of each of the redistribution patterns 530 may be provided on the top surface of the wire portion 530W and may be connected to the wire portion 530W without an interface. The width of the wire portion 530W of each of the redistribution patterns 530 may be greater than the width of the via portion 530V.

The redistribution layer 500 may further include seed patterns 535. The seed patterns 535 may be respectively on the top surfaces of the redistribution patterns 530. For example, each of the seed patterns 535 may cover the top surface and sidewall of the via portion 530V and the top surface of the wire portion 530W in the corresponding redistribution pattern 530. The uppermost seed patterns 535 may be provided between the uppermost redistribution patterns 530 and the first and second lower posts 331 and 332. The first and second lower posts 331 and 332 may be respectively on top surfaces of respective ones of the uppermost seed patterns 535. The seed patterns 535 may include a material that is different from a material of the redistribution patterns 530. For example, the seed patterns 535 may each include a conductive seed material. The conductive seed material may include titanium, copper, and/or any alloy thereof. The seed patterns 535 may serve as barrier layers that prevent diffusion of materials included in the redistribution patterns 530.

The redistribution pads 550 may be provided on the bottom surface of the lowermost insulating layer 510 and may further extend to the lowermost insulating layer 510. The lower portion of each of the redistribution pads 550 may be on the bottom surface of the lowermost insulating layer 510. The upper portion of each of the redistribution pads 550 may be in the lowermost insulating layer 510. The lower portion of each of the redistribution pads 550 may have a width greater than a width of the upper portion of corresponding one of the redistribution pads 550 and may be connected to the upper portion of the corresponding one of the redistribution pads 550.

The redistribution layer 500 may further include seed pads 555. The seed pads 555 may be provided on the top surfaces of the redistribution pads 550 and may cover the top surfaces of the redistribution pads 550. The seed pads 555 may be provided between the lowermost redistribution patterns 530 and the redistribution pads 550 and may extend between the lowermost insulating layer 510 and the redistribution pads 550. The seed pads 555 may include a metal material that is different from a metal material of the redistribution pads 550. The seed pads 555 may include, for example, a conductive seed material.

The bridge structure 700 may include a base substrate 710, bridge insulating layers 720, conductive pads 715, bridge wires 730, through-vias 750, and conductive connection portions 751. Herein, the expression “being connected to the bridge structure 700” may mean “being connected to at least one of the bridge wires 730 and the through-vias 750.” The base substrate 710 may be, for example, a semiconductor substrate such as a silicon substrate. As another example, the base substrate 710 may include an organic substrate. The organic substrate may include an insulating polymer. The bridge insulating layers 720 may be stacked on the top surface of the base substrate 710. The bridge insulating layers 720 may each include a silicon-based insulating material or an organic insulating material. The silicon-based insulating material may include, for example, silicon oxide, silicon nitride, silicon oxynitride, silicon carbide oxide, and/or any combination thereof. The organic insulating material may include an insulating polymer. The top surface of the bridge structure 700 may include the top surface of the uppermost bridge insulating layer 720.

The conductive pads 715 may be provided on the top surface of the bridge structure 700. The top surface of the bridge structure 700 may further include the top surface of the uppermost bridge insulating layer 720. The top surfaces of the conductive pads 715 may not be covered with the bridge insulating layers 720. The conductive pads 715 may be spaced laterally apart from each other. For example, one of the conductive pads 715 (e.g., the first conductive pad) may be provided on the first area of the bridge structure 700, and another of the conductive pads 715 (e.g., the second conductive pad) may be provided on the second area of the bridge structure 700. The conductive pads 715 may include metal, such as copper, aluminum, and/or tungsten.

The bridge wires 730 may be provided on the base substrate 710. The bridge wires 730 may be provided between one surface of the bridge insulating layer 720 and one surface of the bridge insulating layer 720 and may be connected to at least two conductive pads 715. For example, the bridge wires 730 may be connected to the first conductive pad and the second conductive pad among the conductive pads 715. The bridge structure 700 may further include connection vias. The connection vias may be between the bridge wires 730 and the conductive pads 715 and may be connected to the bridge wires 730 and the conductive pads 715. The bridge wires 730 and the connection vias may each include metal, such as copper, titanium, and/or tungsten.

The through-vias 750 may penetrate through the base substrate 710. Although not illustrated, the through-vias 750 may further penetrate through the bridge insulating layer 720. The bridge structure 700 may further include conductive connection portions 751. The conductive connection portions 751 may penetrate through at least one of the bridge insulating layers 720 and may be between the through-vias 750 and the conductive pads 715. Some conductive pads 715 may be electrically connected to the through-vias 750 through the conductive connection portions 751.

The bridge structure 700 may not include integrated circuits. Although not illustrated, the bridge structure 700 may further include passive elements, such as capacitors, resistors, and/or inductors.

The semiconductor package 1 may further include bridge solder balls 670. The bridge solder balls 670 may be provided between the bridge structure 700 and the first and second upper bridge posts 317 and 327. For example, the bridge solder balls 670 may be provided between the conductive pads 715 and the first and second upper bridge posts 317 and 327. The bridge solder balls 670 may be directly connected to the top surfaces of the conductive pads 715 and the bottom surfaces of the first and second upper bridge posts 317 and 327. The bridge solder balls 670 may each include a solder material. As an example, the bridge solder balls 670 may each include a eutectic solder material, but the present disclosure is not limited thereto.

When a gap fill film covers the sidewalls of the first and second upper bridge posts 317 and 327 and the sidewalls of the bridge solder balls 670, stress may be applied to the first and second upper bridge posts 317 and 327 and the bridge solder balls 670. The stress may be caused by the difference in CTE between the gap fill film and the second molding layer 420.

According to some embodiments, the second molding layer 420 may extend to the gap area between the bridge structure 700 and the semiconductor device 100 and the gap area between the bridge structure 700 and the second semiconductor chip 200 and further cover the sidewalls of the first and second upper bridge posts 317 and 327 and the sidewalls of the bridge solder balls 670. The second molding layer 420 may further extend to the gap area between the bridge structure 700 and the first molding layer 410. The second molding layer 420 may prevent or reduce application of stress to the first and second upper bridge posts 317 and 327 and the bridge solder balls 670.

The semiconductor package 1 may further include conductive patterns 755. The conductive patterns 755 may be between the redistribution layer 500 and the bridge structure 700. For example, the conductive patterns 755 may be between the through-vias 750 and the corresponding uppermost seed patterns 535 and may be electrically connected to the through-vias 750 and the uppermost seed patterns 535. For example, the conductive patterns 755 may be in direct contact with the top surfaces of the uppermost seed patterns 535. Accordingly, the through-vias 750 may be electrically connected to the redistribution patterns 530 through the conductive patterns 755 and the uppermost seed patterns 535. The conductive patterns 755 may each include a metal material, such as copper, titanium, and/or any alloy thereof. The second molding layer 420 may further extend to the gap area between the redistribution layer 500 and the bridge structure 700 and may cover the sidewalls of the conductive patterns 755 and the bottom surface of the bridge structure 700. The bottom surfaces of the conductive patterns 755 may be at substantially the same level as (e.g., coplanar with) the bottom surface of the first lower post 331, the bottom surface of the second lower post 332, and the bottom surface of the second molding layer 420.

Referring to FIG. 1B again, the semiconductor package 1 may further include a lower underfill film 460. The lower underfill film 460 may be between the package substrate 600 and the redistribution layer 500 and may cover the sidewalls of the connection solder balls 650. The lower underfill film 460 may include an insulating polymer, such as epoxy-based polymer.

FIG. 1D is a diagram for describing the semiconductor package according to embodiments and corresponds to an enlarged view of region II of FIG. 1B.

Referring to FIGS. 1B and 1D together, an underfill film 470 may be further provided. The underfill film 470 may be provided in the gap area between the bridge structure 700 and the semiconductor device 100 and the gap area between the bridge structure 700 and the second semiconductor chip 200 and may cover the sidewalls of the first and second upper bridge posts 317 and 327 and the sidewalls of the bridge solder balls 670. The underfill film 470 may further extend to the gap area between the bridge structure 700 and the first molding layer 410.

The second molding layer 420 may be provided between the top surface of the redistribution layer 500 and the bottom surface 410b of the first molding layer 410 and may further cover the sidewalls of the underfill film 470. The underfill film 470 may include a material that is different from a material of the second molding layer 420, but the present disclosure is not limited thereto. For example, the underfill film 470 may include an insulating polymer, such as epoxy polymer. According to some embodiments, because the underfill film 470 is provided, the space between the first and second upper bridge posts 317 and 327 and the space between the bridge solder balls 670 may be filled with the underfill film 470 in a relatively satisfactory manner. For example, the formation of voids between the first and second upper bridge posts 317 and 327 and between the bridge solder balls 670 may be prevented.

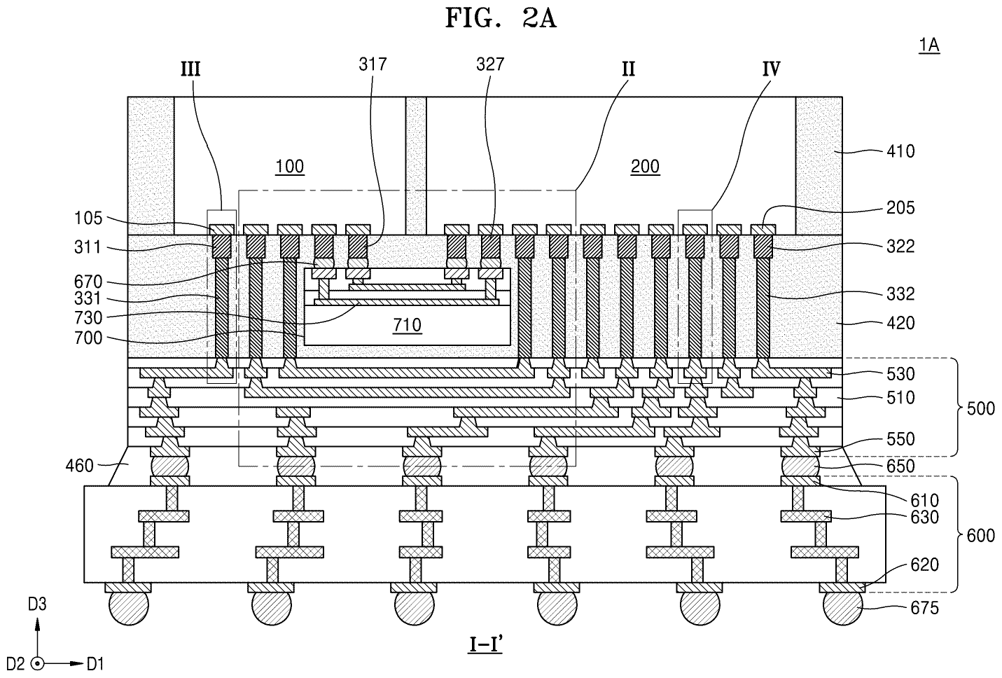

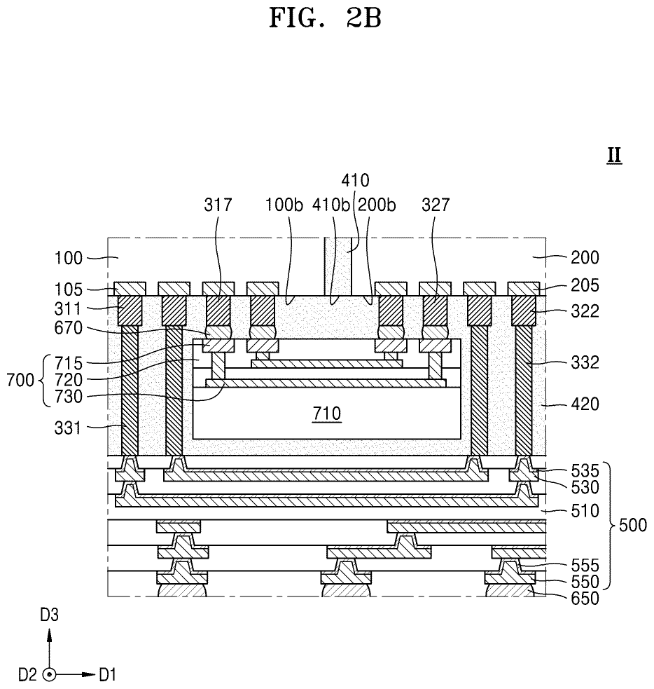

FIG. 2A is a cross-sectional view for describing a semiconductor package 1A according to some embodiments and corresponds to a cross-section taken along line I-I′ of FIG. 1A. FIG. 2B is an enlarged view of region II of FIG. 1B. Also, some descriptions redundant with those provided above may be omitted in the interest of brevity.

Referring to FIGS. 2A and 2B, the semiconductor package 1A may include a package substrate 600, solder ball terminals 675, a redistribution layer 500, a first lower post 331, a second lower post 332, a bridge structure 700, first upper posts 311 and 317, second upper posts 322 and 327, a semiconductor device 100, a second semiconductor chip 200, a first molding layer 410, and a second molding layer 420. The semiconductor device 100 may include a first lower semiconductor chip (see 110 of FIG. 1B).

As described in the example of FIG. 1C, the bridge structure 700 may include a base substrate 710, bridge insulating layers 720, conductive pads 715, and bridge wires 730. However, in contrast to that illustrated in FIG. 1C, the bridge structure 700 may not include through-vias 750 and conductive connection portions 751. The semiconductor package 1A may not include the conductive patterns 755 described in the example of FIG. 1C. The bottom surface of the bridge structure 700 may be spaced vertically apart from the redistribution layer 500. The second molding layer 420 may further fill the gap between the top surface of the redistribution layer 500 and the bottom surface of the bridge structure 700.

The second semiconductor chip 200 may be electrically connected to the semiconductor device 100 through the bridge wires 730. In this case, the electrical connection between the second semiconductor chip 200 and the semiconductor device 100 through the bridge wires 730 may be performed via the first and second upper bridge posts 317 and 327 and the bridge solder balls 670.

The second semiconductor chip 200 may be electrically connected to the semiconductor device 100 and the redistribution layer 500. In this case, the electrical connection between the second semiconductor chip 200 and the semiconductor device 100 through the redistribution layer 500 may be achieved via the first and second upper connection posts 311 and 322 and the first and second lower posts 331 and 332.

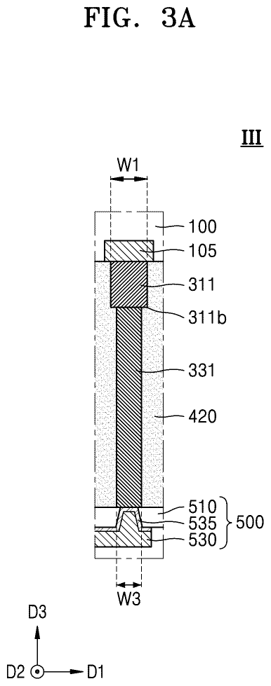

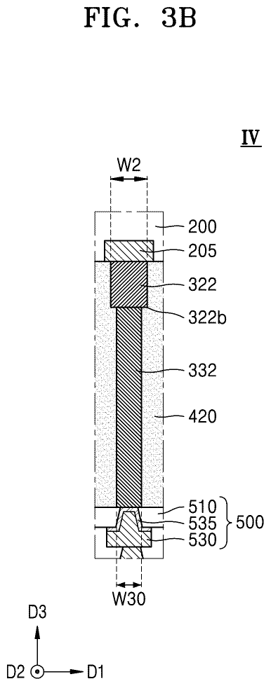

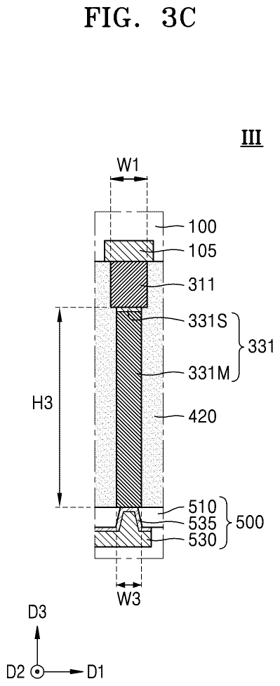

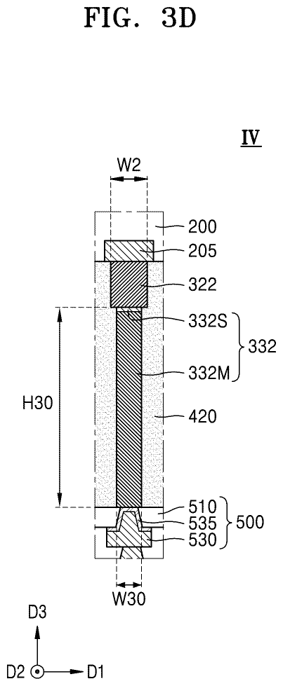

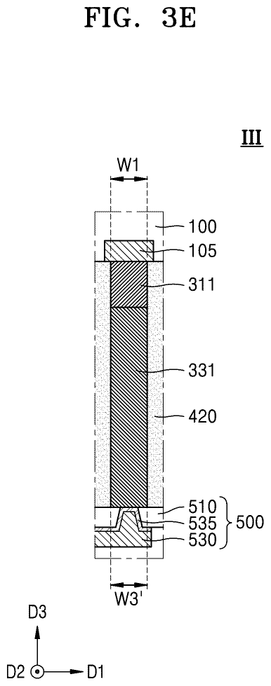

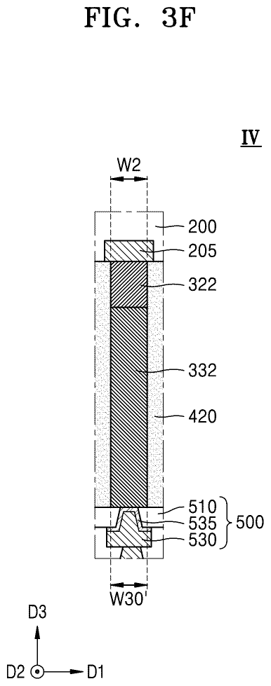

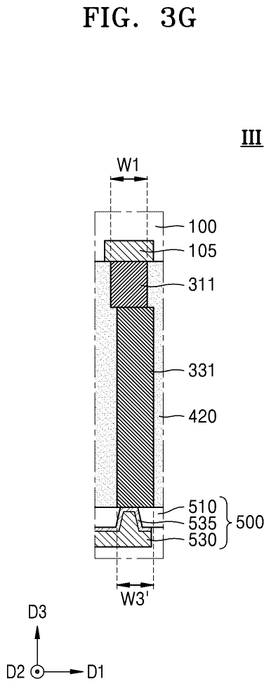

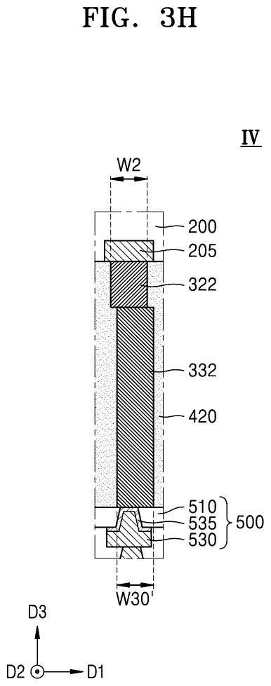

FIG. 3A is a diagram for describing the first upper connection post 311 and the first lower post 331 according to some embodiments and is an enlarged view of region III of FIG. 2A. Also, some descriptions redundant with those provided above may be omitted herein in the interest of brevity.

Referring to FIG. 3A, the first lower post 331 may be in contact with the bottom surface of the first upper connection post 311. The width W3 of the first lower post 331 may be less than the width W1 of the first upper connection post 311. Accordingly, the first lower post 331 may be spaced apart from a portion 311b of the bottom surface of the first upper connection post 311. The portion 311b of the bottom surface of the first upper connection post 311 may be an edge area of the bottom surface of the first upper connection post 311, but the present disclosure is not limited thereto. The first molding layer 410 may further cover the portion 311b of the bottom surface of the first upper connection post 311.

FIG. 3B is a diagram for describing the second upper connection post 322 and the second lower post 332 according to some embodiments and is an enlarged view of region IV of FIG. 2A.

Referring to FIG. 3B, the second lower post 332 may be in contact with the bottom surface of the second upper connection post 322. The width W30 of the second lower post 332 may be less than the width W2 of the second upper connection post 322. Accordingly, the second lower post 332 may be spaced apart from a portion 321b of the bottom surface of the second upper connection post 322. The portion 321b of the bottom surface of the second upper connection post 322 may be an edge area of the bottom surface of the second upper connection post 322, but the present disclosure is not limited thereto. The second molding layer 420 may further cover the portion 321b of the bottom surface of the second upper connection post 322.

FIG. 3C is a diagram for describing the first upper connection post 311 and the first lower post 331 according to some embodiments and is an enlarged view of region III of FIG. 2A.

Referring to FIG. 3C, the first lower post 331 may include a first seed film 331S and a first metal post 331M. The first seed film 331S may be provided between the first metal post 331M and the first upper connection post 311. For example, the first seed film 331S may be provided on the bottom surface of the first upper connection post 311. The first seed film 331S may include a metal material that is different from a metal material of each of the first metal post 331M and the first upper connection post 311. For example, the first seed film 331S may include titanium or a copper-titanium alloy.

The first metal post 331M may be on the bottom surface of the first seed film 331S. The first metal post 331M may be on the top surface of the redistribution layer 500. For example, the first metal post 331M may be in direct contact with the top surface of the corresponding uppermost seed pattern 535. The forming of the first metal post 331M may include performing a plating process using the first seed film 331S as an electrode. The width of the first metal post 331M may be substantially equal to the width of the first seed film 331S. The sidewalls of the first upper connection post 311 may be vertically aligned with the sidewalls of the first seed film 331S. The first metal post 331M may include the same metal as the first upper connection post 311.

The height H3 of the first lower post 331 may be equal to the sum of the thickness of the first seed film 331S and the height of the first metal post 331M. The thickness of the first seed film 331S may be less than the height of the first metal post 331M. The width W3 of the first lower post 331 may be less than or equal to the width W1 of the first upper connection post 311.

FIG. 3D is a diagram for describing the second upper connection post 322 and the second lower post 332 according to some embodiments and is an enlarged view of region IV of FIG. 2A.

Referring to FIG. 3D, the second lower post 332 may include a second seed film 332S and a second metal post 332M. The second seed film 332S may be provided between the second metal post 332M and the second upper connection post 322. For example, the second seed film 332S may be provided on the bottom surface of the second upper connection post 322. The second seed film 332S may include a metal material that is different from a metal material of each of the second metal post 332M and the second upper connection post 322. For example, the second seed film 332S may include titanium or a copper-titanium alloy.

The second metal post 332M may be on the bottom surface of the second seed film 332S. The second metal post 332M may be between the redistribution layer 500 and the second seed film 332S. For example, the second metal post 332M may be in direct contact with the top surface of the corresponding uppermost seed pattern 535. The forming of the second metal post 332M may include performing a plating process using the second seed film 332S as an electrode. The width of the second metal post 332M may be substantially equal to the width of the second seed film 332S. The sidewalls of the second upper connection post 322 may be vertically aligned with the sidewalls of the second seed film 332S. The width W30 of the second lower post 332 may be less than or equal to the width W2 of the second upper connection post 322. The second metal post 332M may include the same metal as the second upper connection post 322.

The height H30 of the second lower post 332 may be equal to the sum of the thickness of the second seed film 332S and the height of the second metal post 332M. The thickness of the second seed film 332S may be less than the height of the second metal post 332M.

FIG. 3E is a diagram for describing the first upper connection post 311 and the first lower post 331 according to some embodiments and is an enlarged view of region III of FIG. 2A.

Referring to FIG. 3E, the first lower post 331 may be on the bottom surface of the first upper connection post 311. The width W3′ of the first lower post 331 may be substantially equal to the width W1 of the first upper connection post 311. The sidewalls of the first lower post 331 may be vertically aligned with the sidewalls of the first upper connection post 311.

FIG. 3F is a diagram for describing the second upper connection post 322 and the second lower post 332 according to embodiments and is an enlarged view of region IV of FIG. 2A.

Referring to FIG. 3F, the second lower post 332 may be on the bottom surface of the second upper connection post 322. The width W30′ of the second lower post 332 may be substantially equal to the width W2 of the second upper connection post 322. The sidewalls of the second upper connection post 322 may be vertically aligned with the sidewalls of the second lower post 332.

FIG. 3G is a diagram for describing the first upper connection post 311 and the first lower post 331 according to embodiments and is an enlarged view of region III of FIG. 2A.

Referring to FIG. 3G, the first lower post 331 may be between the top surface of the redistribution layer 500 and the bottom surface of the first upper connection post 311. The first upper connection post 311 may be offset from the first lower post 331 in the first direction D1 or in a direction opposite to the first direction D1. The sidewalls of the first upper connection post 311 may be offset from the sidewalls of the first lower post 331 in the first direction D1 or in a direction opposite to the first direction D1. The sidewalls of the first upper connection post 311 may not be vertically aligned with the sidewalls of the first lower post 331.

The width W3′ of the first lower post 331 may be less than the width W1 of the first upper connection post 311. In contrast, the width W3′ of the first lower post 331 may be substantially equal to the width W1 of the first upper connection post 311.

FIG. 3H is a diagram for describing the second upper connection post 322 and the second lower post 332 according to some embodiments and is an enlarged view of region IV of FIG. 2A.

Referring to FIG. 3H, the second lower post 332 may be between the top surface of the redistribution layer 500 and the bottom surface of the second upper connection post 322. The second upper connection post 322 may be offset from the second lower post 332 in the first direction D1 or in a direction opposite to the first direction D1. The sidewalls of the second upper connection post 322 may be offset from the sidewalls of the second lower post 332 in the first direction D1 or in a direction opposite to the first direction D1. The sidewalls of the second upper connection post 322 may not be vertically aligned with the sidewalls of the second lower post 332.

The width W30′ of the second lower post 332 may be less than the width W2 of the second upper connection post 322. In contrast, the width W30′ of the second lower post 332 may be substantially equal to the width W2 of the second upper connection post 322.

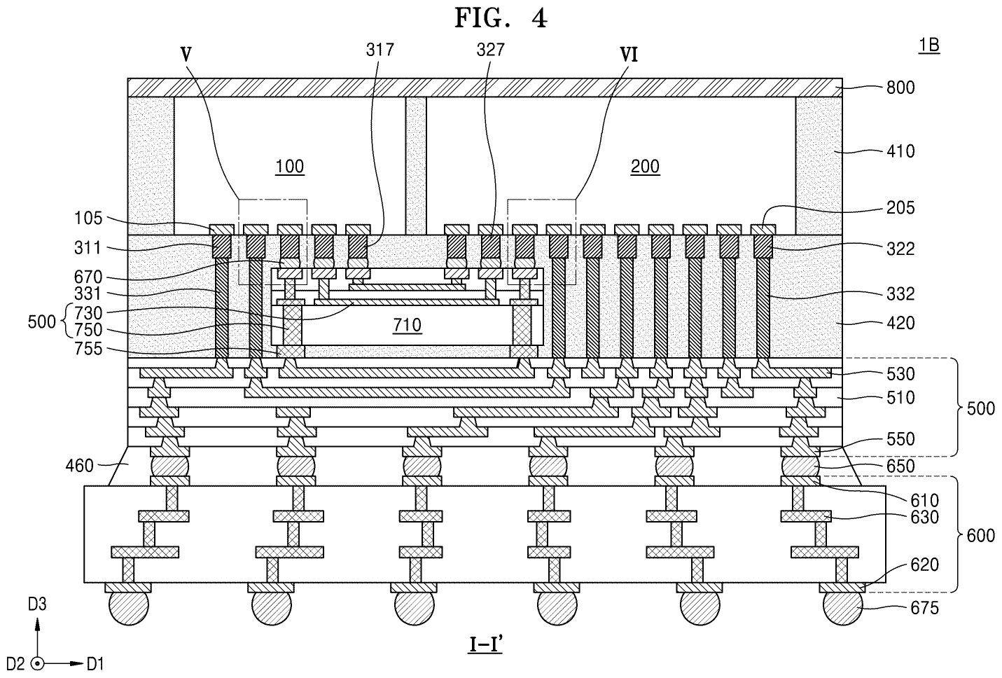

FIG. 4 is a cross-sectional view for describing a semiconductor package 1B according to some embodiments and corresponds to a cross-section taken along line I-I′ of FIG. 1A.

Referring to FIG. 4, the semiconductor package 1B may include a package substrate 600, solder ball terminals 675, a redistribution layer 500, first and second lower posts 331 and 332, a bridge structure 700, bridge solder balls 670, first upper posts 311 and 317, second upper posts 322 and 327, a semiconductor device 100, a second semiconductor chip 200, a first molding layer 410, a second molding layer 420, and a heat dissipation structure 800. The semiconductor device 100 may include a first lower semiconductor chip (see 110 of FIG. 1B).

The second molding layer 420 may be spaced apart from the top surface of the semiconductor device 100 and the top surface of the second semiconductor chip 200, without extending onto the top surface of the semiconductor device 100 and the top surface of the second semiconductor chip 200. For example, the top surface of the second molding layer 420 may be coplanar with the top surface of the semiconductor device 100 and the top surface of the second semiconductor chip 200.

The heat dissipation structure 800 may be on the top surface of the semiconductor device 100 and the top surface of the second semiconductor chip 200 and may be in physical contact (e.g., direct physical contact) with the top surface of the semiconductor device 100 and the top surface of the second semiconductor chip 200. The heat dissipation structure 800 may further extend onto the top surface of the second molding layer 420. The heat dissipation structure 800 may include a material with high thermal conductivity. Accordingly, when the semiconductor package 1B operates, heat generated from the semiconductor device 100 or the second semiconductor chip 200 may be dissipated relatively quickly through the heat dissipation structure 800. The semiconductor package 1B may exhibit improved thermal and operational characteristics. The heat dissipation structure 800 may protect the semiconductor device 100 and the second semiconductor chip 200 by absorbing external physical impact.

The heat dissipation structure 800 may include a heat dissipation plate. The heat dissipation plate may include a heat slug or a heat sink. The heat dissipation plate may include metal (e.g., copper and/or aluminum, etc.) or a carbon-containing material (e.g., graphene, graphite, and/or carbon nanotubes, etc.). As an example, a single metal layer or a plurality of stacked metal layers may be used as the heat dissipation structure 800.

The heat dissipation structure 800 may further include a thermal interface material (TIM) layer. The TIM layer may be between the semiconductor device 100 and the heat dissipation plate and between the second semiconductor chip 200 and the heat dissipation plate. The TIM layer may further extend between the second molding layer 420 and the heat dissipation plate. The TIM layer may include, for example, polymer and thermally conductive particles. The thermally conductive particles may be dispersed within the polymer. The thermally conductive particles may include metal. The TIM layer may have a thermal conductivity greater than a thermal conductivity of air. Because the TIM layer is provided, heat generated from the semiconductor device 100 and the second semiconductor chip 200 may be more efficiently transmitted to the heat dissipation plate through the TIM layer.

Because the heat dissipation structure 800 has electrical conductivity, the heat dissipation structure 800 may further serve as an electromagnetic shielding layer. For example, the heat dissipation structure 800 may shield electromagnetic interference (EMI) of the semiconductor device 100 and the second semiconductor chip 200.

In some embodiments, the heat dissipation structure 800 may further extend onto the sidewalls of the first molding layer 410 and the second molding layer 420. The heat dissipation structure 800 may be grounded through the redistribution layer 500 or the package substrate 600, and thus, electrical damage to the semiconductor device 100 or the second semiconductor chip 200 due to electrostatic discharge (ESD) may be prevented.

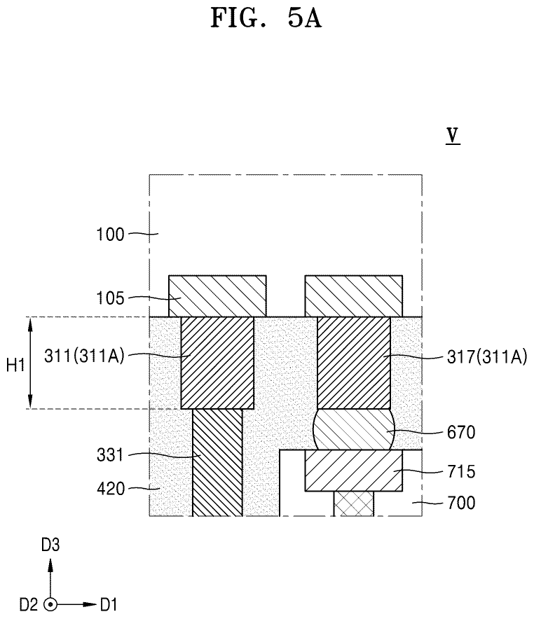

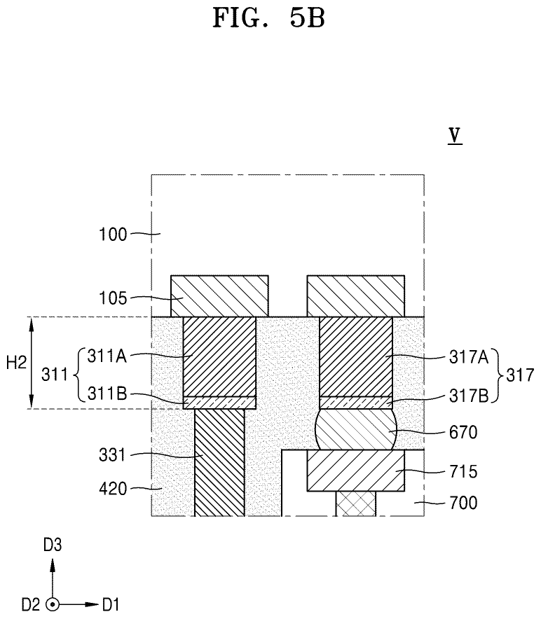

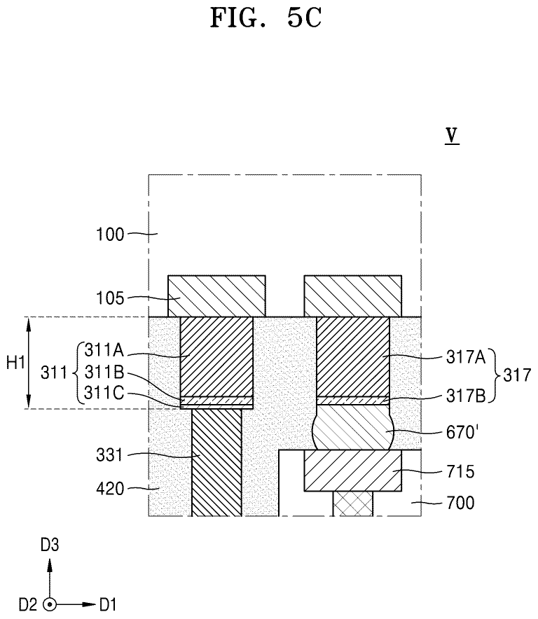

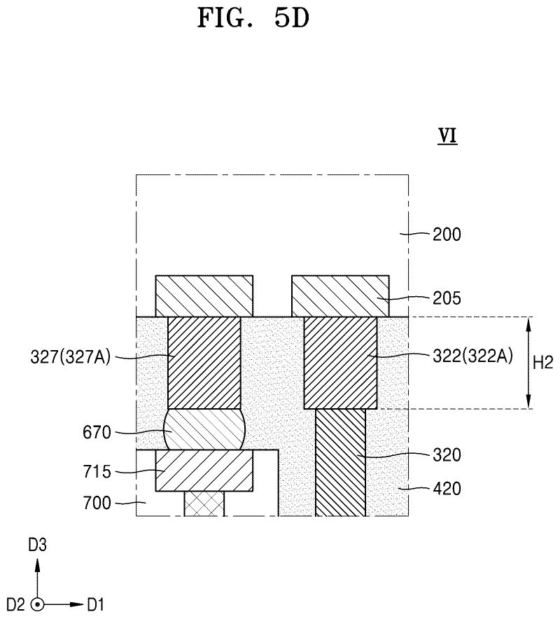

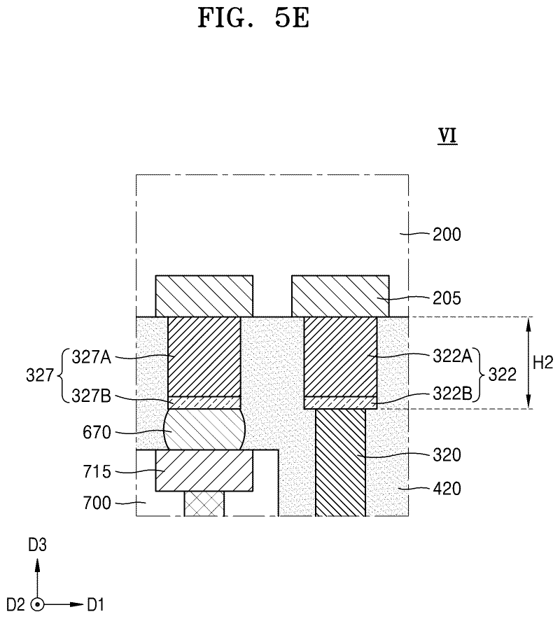

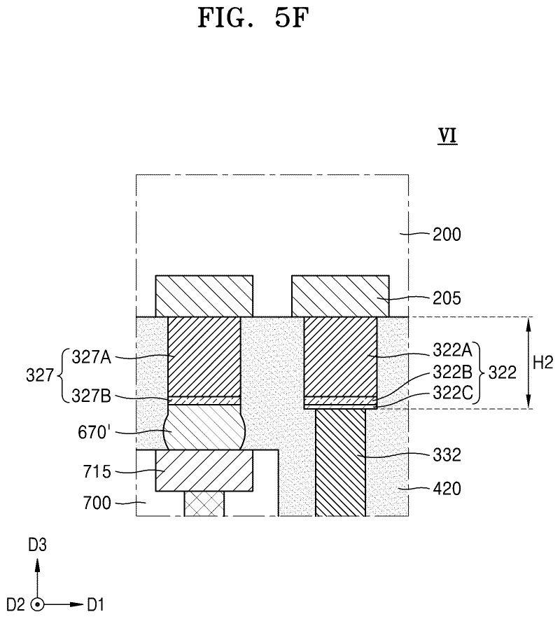

FIG. 5A is a diagram for describing the first upper connection post 311 and the first upper bridge post 317 according to some embodiments and is an enlarged view of region V of FIG. 4. Also, some descriptions redundant with those provided above may be omitted herein in the interest of brevity. In the description of FIGS. 5A and 5F, a single bridge solder ball is described for simplicity.

Referring to FIGS. 4 and 5A, the first upper connection post 311 may include a first connection conductive post 311A. The first connection conductive post 311A may be on the bottom surface of one of the first lower pads 105. The first connection conductive post 311A may be in direct contact with the bottom surface of one of the first lower pads 105. The first connection conductive post 311A may include copper or a copper alloy. The first lower post 331 may be in direct contact with the bottom surface of the first connection conductive post 311A. The height H1 of the first upper connection post 311 may be equal to the height of the first connection conductive post 311A.

The first upper bridge post 317 may include a first bridge conductive post 317A. The first bridge conductive post 317A may be on the bottom surface of another first lower pad 105. The first bridge conductive post 317A may be in direct contact with the bottom surface of the other first lower pad 105. The bridge solder ball 670 may be in direct contact with the bottom surface of the first bridge conductive post 317A. The first bridge conductive post 317A may be formed through a single process with the first connection conductive post 311A. The height of the first bridge conductive post 317A may be substantially equal to the height of the first connection conductive post 311A, and the material of the first bridge conductive post 317A may be substantially the same as the material of the first connection conductive post 311A.

FIG. 5B is a diagram for describing the first upper connection post 311 and the first upper bridge post 317 according to some embodiments and is an enlarged view of region V of FIG. 4.

Referring to FIG. 5B, the first upper connection post 311 may include a first connection conductive post 311A and a first connection metal layer 311B. The first connection conductive post 311A may be in direct contact with the bottom surface of one of the first lower pads 105. The first connection conductive post 311A may include the material described in the example of FIG. 5A.

The first connection metal layer 311B may be on the bottom surface of the first connection conductive post 311A. The first connection metal layer 311B may include a different metal from the first connection conductive post 311A and the first lower post 331. For example, the first connection metal layer 311B may include nickel or a nickel alloy. The first connection metal layer 311B may serve as a barrier film. The first connection metal layer 311B may prevent the metal included in the first connection conductive post 311A from moving. The first lower post 331 may be in direct contact with the bottom surface of the first connection metal layer 311B.

The height H1 of the first upper connection post 311 may be equal to the sum of the thickness of the first connection metal layer 311B and the height of the first connection conductive post 311A. The thickness of the first connection metal layer 311B may be less than the height of the first connection conductive post 311A.

The first upper bridge post 317 may include a first bridge conductive post 317A and a first bridge metal layer 317B. The first bridge conductive post 317A may be in direct contact with the bottom surface of another first lower pad 105.

The first bridge metal layer 317B may be on the bottom surface of the first bridge conductive post 317A. The first bridge metal layer 317B may be formed through a single process with the first connection metal layer 311B. The height of the first bridge metal layer 317B may be substantially equal to the height of the first connection metal layer 311B, and the material of the first bridge metal layer 317B may be substantially the same as the material of the first connection metal layer 311B. For example, the first bridge metal layer 317B may include nickel or a nickel alloy. The first bridge metal layer 317B may serve as a barrier film. The first bridge metal layer 317B may prevent the metal included in the first bridge conductive post 317A from moving. For example, the first bridge metal layer 317B may prevent the metal included in the first bridge conductive post 317A from moving into the bridge solder ball 670. The first bridge conductive post 317A may be spaced apart from the bridge solder ball 670 by the first bridge metal layer 317B. The first lower post 331 may be in direct contact with the bottom surface of the first bridge metal layer 317B.

The height of the first upper bridge post 317 may be equal to the sum of the thickness of the first bridge metal layer 317B and the height of the first bridge conductive post 317A. The thickness of the first bridge metal layer 317B may be less than the height of the first bridge conductive post 317A.

FIG. 5C is a diagram for describing the first upper connection post 311 and the first upper bridge post 317 according to some embodiments and is an enlarged view of region V of FIG. 4.

Referring to FIG. 5C, the first upper connection post 311 may include a first connection conductive post 311A, a first connection metal layer 311B, and a first connection bonding layer 311C. The first connection conductive post 311A and the first connection metal layer 311B may be similar to those described in the example of FIG. 5B.

The first connection bonding layer 311C may be on the bottom surface of the first connection metal layer 311B. The first connection bonding layer 311C may include a different metal material than the first connection conductive post 311A, the first connection metal layer 311B, and the first lower post 331. For example, the first connection bonding layer 311C may include Au or an Au alloy. The first connection bonding layer 311C may prevent oxidation of the first upper connection post 311. For example, the first connection bonding layer 311C may prevent oxidation of the first connection metal layer 311B or the first connection conductive post 311A. The thickness of the first connection bonding layer 311C may be less than the thickness of the first connection metal layer 311B and the height of the first connection conductive post 311A. The height H1 of the first upper connection post 311 may be equal to the sum of the height of the first connection conductive post 311A, the thickness of the first connection metal layer 311B, and the thickness of the first connection bonding layer 311C. The first lower post 331 may be directly connected to the bottom surface of the first connection bonding layer 311C.

The first upper bridge post 317 may include a first bridge conductive post 317A and a first bridge metal layer 317B, but may not include a first bridge bonding layer. The height of the first bridge conductive post 317A may be substantially equal to the height of the first connection conductive post 311A, and the material of the first bridge conductive post 317A may be substantially the same as the material of the first connection conductive post 311A. The height of the first bridge metal layer 317B may be substantially equal to the height of the first connection metal layer 311B, and the material of the first bridge metal layer 317B may be substantially the same as the material of the first connection metal layer 311B. For example, the bottom surface of the first bridge metal layer 317B may be at substantially the same level as (e.g., coplanar with) the bottom surface of the first connection metal layer 311B.

A bridge solder ball 670′ may be in direct contact with the bottom surface of the first bridge metal layer 317B. The bridge solder ball 670′ may further include the same metal as the first connection bonding layer 311C in addition to a solder material. For example, the bridge solder ball 670′ may include a solder material and Au. In a reflow process of the bridge solder ball 670′, the metal in the first bridge bonding layer (not shown) of the first upper bridge post 317 may move into the bridge solder ball 670′ to form an intermetallic compound (IMC) with the solder material. Accordingly, after the reflow process, the first bridge bonding layer of the first upper bridge post 317 may not remain. The height of the first upper bridge post 317 may be equal to the sum of the height of the first bridge conductive post 317A and the thickness of the first bridge metal layer 317B.

FIG. 5D is a diagram for describing the second upper connection post 322 and the second upper bridge post 327 according to some embodiments and corresponds to an enlarged view of region VI of FIG. 4.

Referring to FIG. 5D, the second upper connection post 322 may include a second connection conductive post 322A. The second connection conductive post 322A may be on the bottom surface of one of the chip pads 205. The second connection conductive post 322A may be in direct contact with the bottom surface of one of the chip pads 205. The second connection conductive post 322A may include copper or a copper alloy. The second lower post 332 may be in direct contact with the bottom surface of the second connection conductive post 322A. The height H2 of the second upper connection post 322 may be equal to the height of the second connection conductive post 322A.

The second upper bridge post 327 may include a second bridge conductive post 327A. The second bridge conductive post 327A may be on the bottom surface of another chip pad 205. The second bridge conductive post 327A may be in direct contact with the bottom surface of the other chip pad 205. The bridge solder ball 670 may be in direct contact with the bottom surface of the second bridge conductive post 327A. The second bridge conductive post 327A may be formed through a single process with the second connection conductive post 322A. The height of the second bridge conductive post 327A may be substantially equal to the height of the second connection conductive post 322A, and the material of the second bridge conductive post 327A may be substantially the same as the material of the second connection conductive post 322A.

FIG. 5E is a diagram for describing the second upper connection post 322 and the second upper bridge post 327 according to some embodiments and corresponds to an enlarged view of region VI of FIG. 4.

Referring to FIG. 5E, the second upper connection post 322 may include a second connection conductive post 322A and a second connection metal layer 322B. The second connection conductive post 322A may be in direct contact with the bottom surface of the chip pad 205. The second connection conductive post 322A may include the material described in the example of FIG. 5D.

The second connection metal layer 322B may be on the bottom surface of the second connection conductive post 322A. The second connection metal layer 322B may include a different metal than the second connection conductive post 322A and the second lower post 332. For example, the second connection metal layer 322B may include nickel or a nickel alloy. The second connection metal layer 322B may serve as a barrier film. The second connection metal layer 322B may prevent the metal included in the second connection conductive post 322A from moving. The second lower post 332 may be in direct contact with the bottom surface of the second connection metal layer 322B.

The height H2 of the second upper connection post 322 may be equal to the sum of the thickness of the second connection metal layer 322B and the height of the second connection conductive post 322A. The thickness of the second connection metal layer 322B may be less than the height of the second connection conductive post 322A.

The second upper bridge post 327 may include a second bridge conductive post 327A and a second bridge metal layer 327B. The second bridge conductive post 327A may be in direct contact with a bottom surface of another chip pad 205.

The second bridge metal layer 327B may be on the bottom surface of the second bridge conductive post 327A. The second bridge metal layer 327B may be formed through a single process with the second connection metal layer 322B. The height of the second bridge metal layer 327B may be substantially equal to the height of the second connection metal layer 322B, and the material of the second bridge metal layer 327B may be substantially the same as the material of the second connection metal layer 322B. For example, the second bridge metal layer 327B may include nickel or a nickel alloy. The second bridge metal layer 327B may serve as a barrier film. The second bridge metal layer 327B may prevent the metal included in the second bridge conductive post 327A from moving. For example, the second bridge metal layer 327B may prevent the metal included in the second bridge conductive post 327A from moving into the bridge solder ball 670. The second bridge conductive post 327A may be spaced apart from the bridge solder ball 670 by the second bridge metal layer 327B. The second lower post 332 may be in direct contact with the bottom surface of the second bridge metal layer 327B.

The height of the second upper bridge post 327 may be equal to the sum of the thickness of the second bridge metal layer 327B and the height of the second bridge conductive post 327A. The thickness of the second bridge metal layer 327B may be less than the height of the second bridge conductive post 327A.

FIG. 5F is a diagram for describing the second upper connection post 322 and the second upper bridge post 327 according to some embodiments and corresponds to an enlarged view of region VI of FIG. 4.

Referring to FIG. 5F, the second upper connection post 322 may include a second connection conductive post 322A, a second connection metal layer 322B, and a second connection bonding layer 322C. The second connection conductive post 322A and the second connection metal layer 322B may be similar to those described in the example of FIG. 5E.

The second connection bonding layer 322C may be on the bottom surface of the second connection metal layer 322B. The second connection bonding layer 322C may include a different metal material than the second connection conductive post 322A, the second connection metal layer 322B, and the second lower post 332. For example, the second connection bonding layer 322C may include Au or an Au alloy. The second connection bonding layer 322C may prevent oxidation of the second upper connection post 322. For example, the second connection bonding layer 322C may prevent oxidation of the second connection metal layer 322B or the second connection conductive post 322A. The thickness of the second connection bonding layer 322C may be less than the thickness of the second connection metal layer 322B and the height of the second connection conductive post 322A. The height H2 of the second upper connection post 322 may be equal to the sum of the height of the second connection conductive post 322A, the thickness of the second connection metal layer 322B, and the thickness of the second connection bonding layer 322C. The second lower post 332 may be directly connected to the bottom surface of the second connection bonding layer 322C.

The second upper bridge post 327 may include a second bridge conductive post 327A and a second bridge metal layer 327B, but may not include a second bridge bonding layer. The height of the second bridge conductive post 327A may be substantially equal to the height of the second connection conductive post 322A, and the material of the second bridge conductive post 327A may be substantially the same as the material of the second connection conductive post 322A. The height of the second bridge metal layer 327B may be substantially equal to the height of the second connection metal layer 322B, and the material of the second bridge metal layer 327B may be substantially the same as the material of the second connection metal layer 322B. For example, the bottom surface of the second bridge metal layer 327B may be at substantially the same level as (e.g., coplanar with) the bottom surface of the second connection metal layer 322B.

A bridge solder ball 670′ may be in direct contact with the bottom surface of the second bridge metal layer 327B. The bridge solder ball 670′ may further include the same metal as the second connection bonding layer 322C in addition to a solder material. For example, the bridge solder ball 670′ may include a solder material and Au. In a reflow process of the bridge solder ball 670′, the metal in the first bridge bonding layer (not shown) of the second upper bridge post 327 may move into the bridge solder ball 670′ to form an IMC with the solder material. Accordingly, after the reflow process, the second bridge bonding layer of the second upper bridge post 327 may not remain. The height of the second upper bridge post 327 may be equal to the sum of the height of the second bridge conductive post 327A and the thickness of the second bridge metal layer 327B.

Various aspects of the examples of embodiments provided herein may be combined with each other. For example, aspects of at least two of the embodiment of FIGS. 1A to 1D, the embodiment of FIG. 1E, the embodiment of FIGS. 2A and 2B, the embodiment of FIG. 3A, the embodiment of FIG. 3B, the embodiment of FIG. 3D, the embodiment of FIG. 3E, the embodiment of FIG. 4, the embodiment of FIG. 5A, the embodiment of FIG. 5B, the embodiment of FIG. 5C, the embodiment of FIG. 5D, the embodiment of FIG. 5E, and the embodiment of FIG. 5F may be combined with each other. For example, the first upper connection post 311 may include the first connection conductive post 311A, as illustrated in FIG. 5A, and the second upper connection post 322 may include the first connection conductive post 311A and the first connection metal layer 311B, as illustrated in FIG. 5E. As another example, the first upper connection post 311 may include the first connection conductive post 311A and the first connection metal layer 311B, as illustrated in FIG. 5B, and the first lower post 331 may include the first metal post 311M and the first seed film 331S, as illustrated in FIG. 3B. As another example, the semiconductor package 1B of FIG. 4 may include the underfill film 470 in addition to the heat dissipation structure 800, as illustrated in FIG. 1D.

FIG. 6 is a cross-sectional view for describing a semiconductor device 100 according to some embodiments. Hereinafter, some descriptions redundant with those provided above with reference to FIG. 1B are omitted herein in the interest of brevity.

Referring to FIG. 6, the semiconductor device 100 may include a chip stack or a chip stack package. For example, the semiconductor device 100 may include a first lower semiconductor chip 110 and first upper semiconductor chips 120. The semiconductor device 100 may further include an inner molding layer 140.

The first lower semiconductor chip 110 may include first integrated circuits (not shown), first lower pads 105, first penetration structures 113, and first upper pads 111. The first lower pads 105 and the first upper pads 111 may be respectively on the bottom and top surfaces of the first lower semiconductor chip 110. The first penetration structures 113 may penetrate through the first lower semiconductor chip 110. The first upper pads 111 may be electrically connected to the first lower pads 105 through the first penetration structures 113. The first integrated circuits may be provided in the first lower semiconductor chip 110 and may be electrically connected to the first lower pads 105, the first penetration structures 113, and the first upper pads 111. The first lower pads 105, the first penetration structures 113, and the first upper pads 111 may each include metal, such as copper, aluminum, tungsten, nickel, titanium, and any alloy thereof. The width of the first lower semiconductor chip 110 may be greater than the widths of the first upper semiconductor chips 120.

Each of the first upper semiconductor chips 120 may include second integrated circuits, second lower pads 125, second penetration structures 123, and second upper pads 121. However, the uppermost chip among the first upper semiconductor chips 120 may include the second lower pads 125, but may not include the second penetration structures 123 and the second upper pads 121.

The second lower pads 125 may be on the bottom surfaces of the first upper semiconductor chips 120. The second upper pads 121 may be on the top surfaces of the first upper semiconductor chips 120. The second penetration structures 123 may penetrate through the first upper semiconductor chips 120. In each of the first upper semiconductor chips 120, the second upper pads 121 may be electrically connected to the second lower pads 125 through the second penetration structures 123. The first upper semiconductor chips 120 may include second integrated circuits therein. In each of the first upper semiconductor chips 120, the second integrated circuits may be electrically connected to the second lower pads 125, the second penetration structures 123, and the second upper pads 121. The second lower pads 125, the second penetration structures 123, and the second upper pads 121 may each include metal, such as copper, aluminum, tungsten, nickel, titanium, and any alloy thereof.

The semiconductor device 100 may further include bumps 150. Some bumps 150 may be between the first lower semiconductor chip 110 and the lowermost first upper semiconductor chip 120 and may be connected to the first upper pads 111 and the second lower pads 125. Other bumps 150 may be between the first upper semiconductor chips 120 and may be connected to the second upper pads 121 and the second lower pads 125 corresponding thereto. The bumps 150 may each include a solder material. Although not illustrated, the bumps 150 may each further include pillar patterns. The pillar patterns may each include metal, such as copper.

The semiconductor device 100 may further include insulating films 160. The insulating films 160 may be between the first lower semiconductor chip 110 and the lowermost first upper semiconductor chip 120 and between the first upper semiconductor chips 120. The insulating films 160 may cover the sidewalls of the corresponding bumps 150. The insulating films 160 may each include a non-conductive film (NCF), but the present disclosure is not limited thereto.

The inner molding layer 140 may be on the top surface of the first lower semiconductor chip 110 and cover the sidewalls of the first upper semiconductor chips 120. The inner molding layer 140 may include an insulating polymer, such as an EMC. In some embodiments, the insulating films 160 may be omitted and the inner molding layer 140 may further extend between the first lower semiconductor chip 110 and the lowermost first upper semiconductor chip 120 and between the first upper semiconductor chips 120 and may further cover the sidewalls of the bumps 150.

In some embodiments, the semiconductor device 100 may not include the bumps 150 and the insulating films 160. The first lower and upper semiconductor chips 110 and 120 may be directly bonded to each other. For example, the first lower semiconductor chip 110 and the lowermost first upper semiconductor chip 120 may be directly bonded to each other. The first upper semiconductor chips 120 adjacent to each other may be directly bonded to each other.

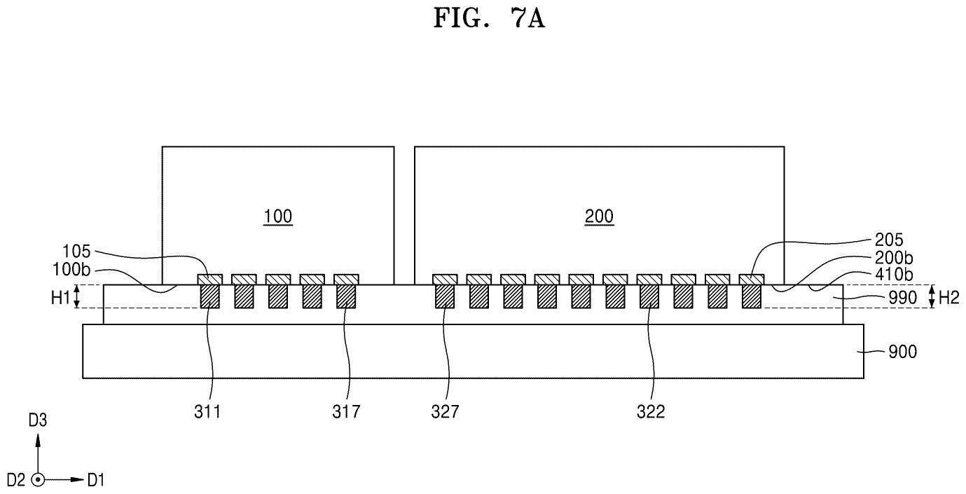

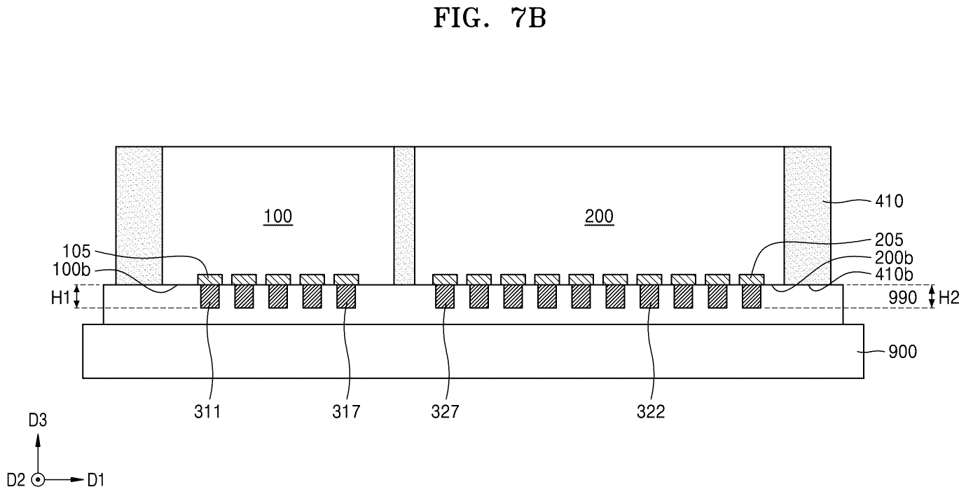

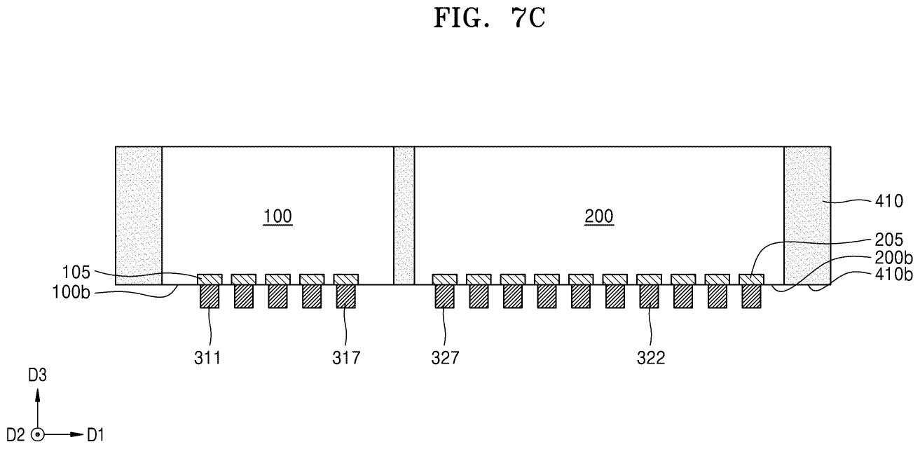

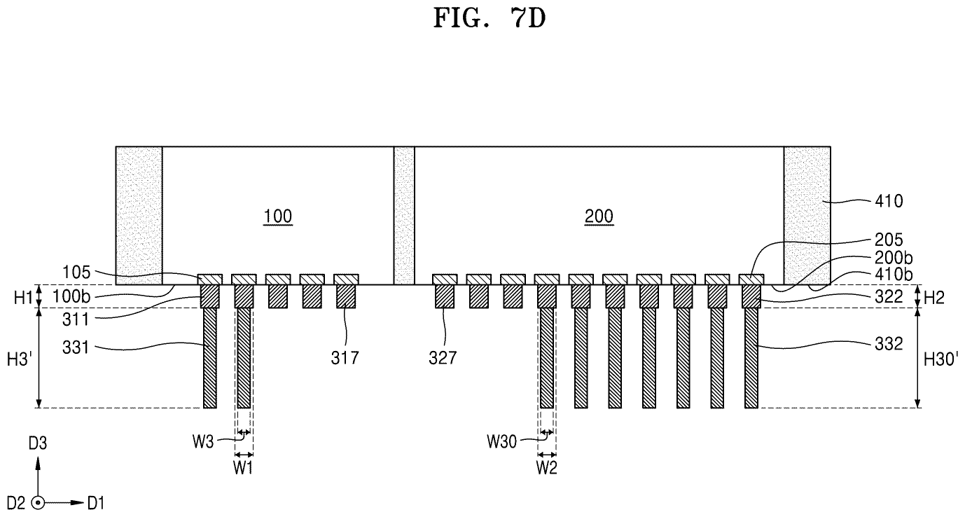

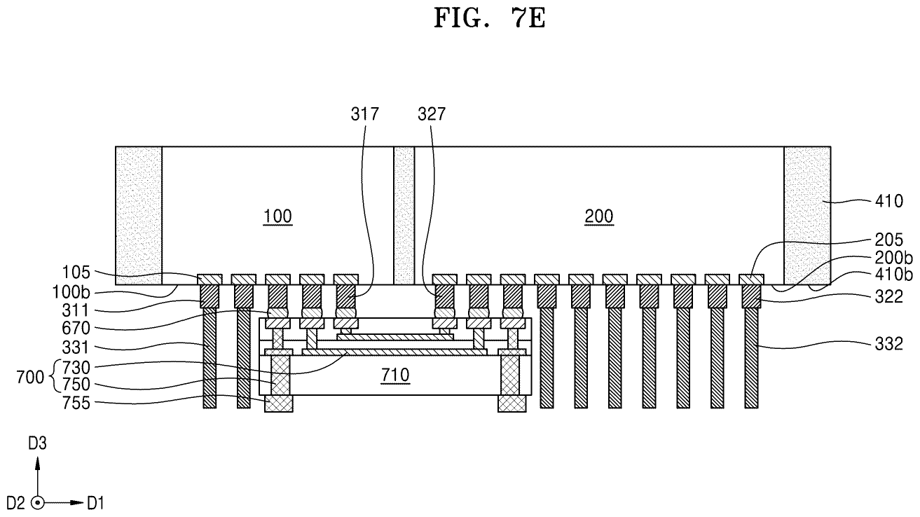

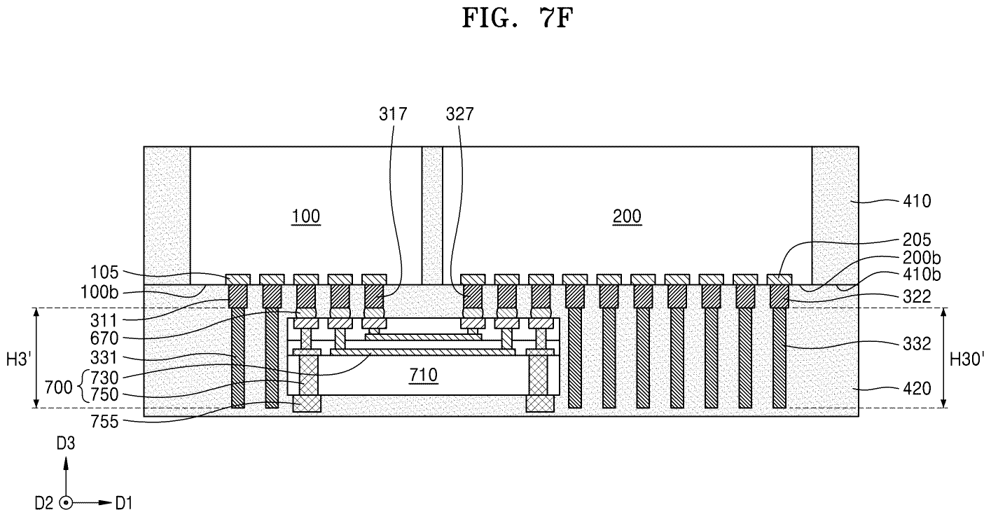

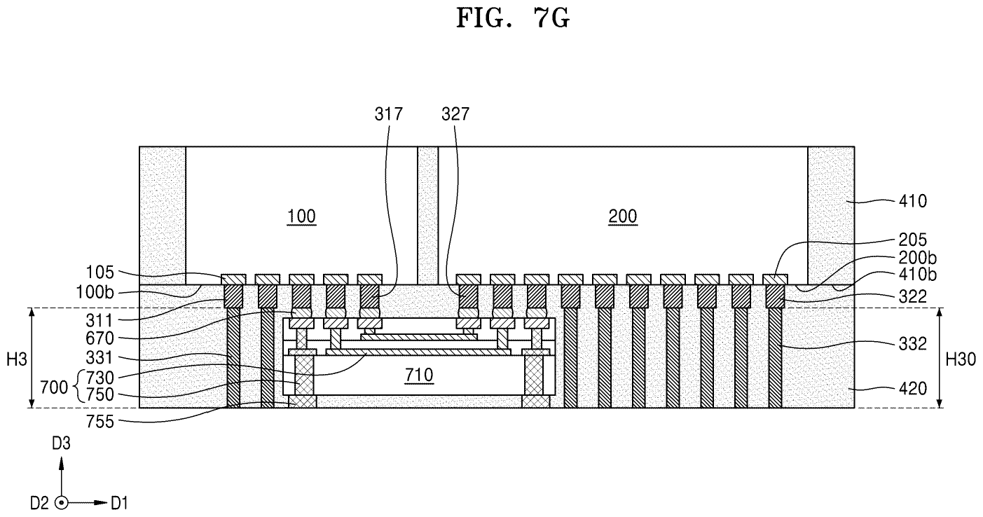

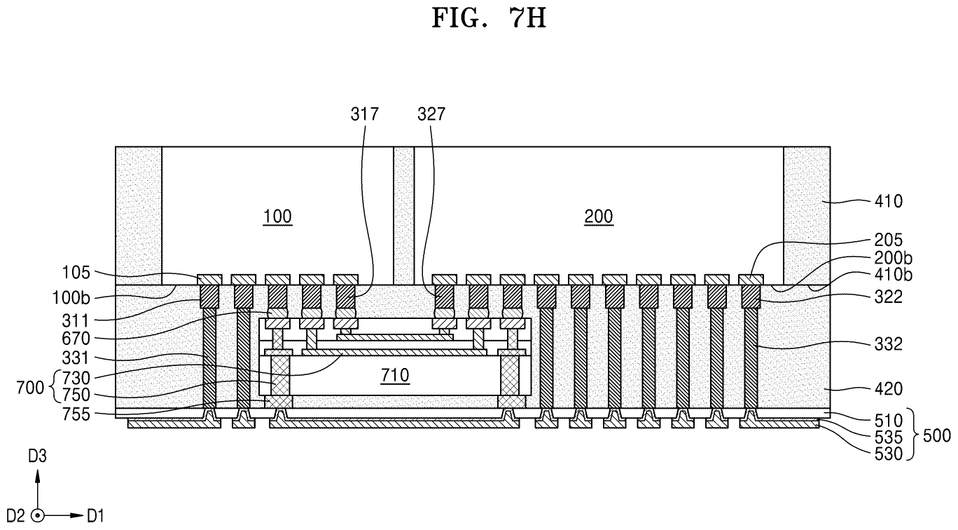

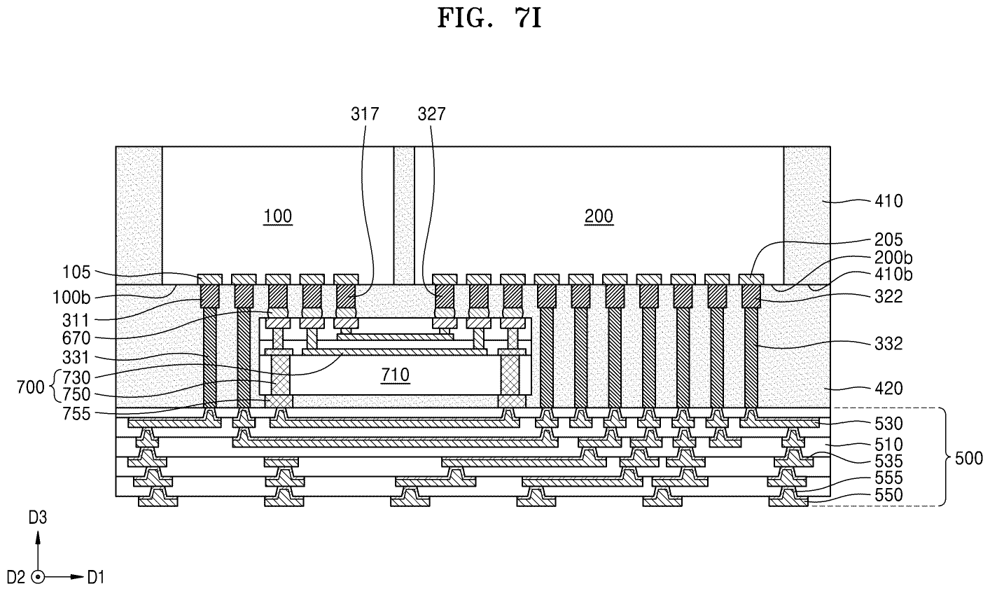

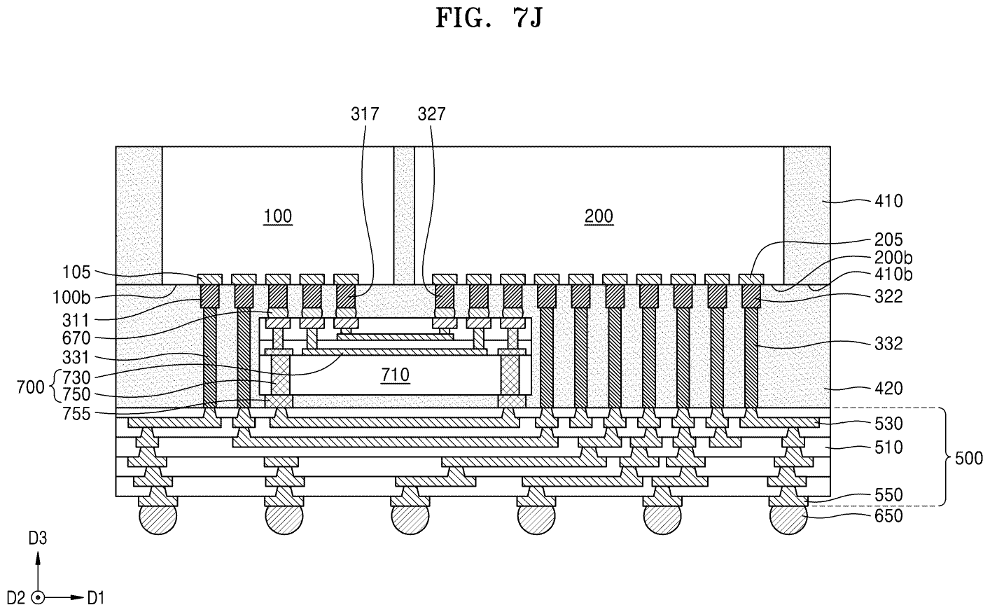

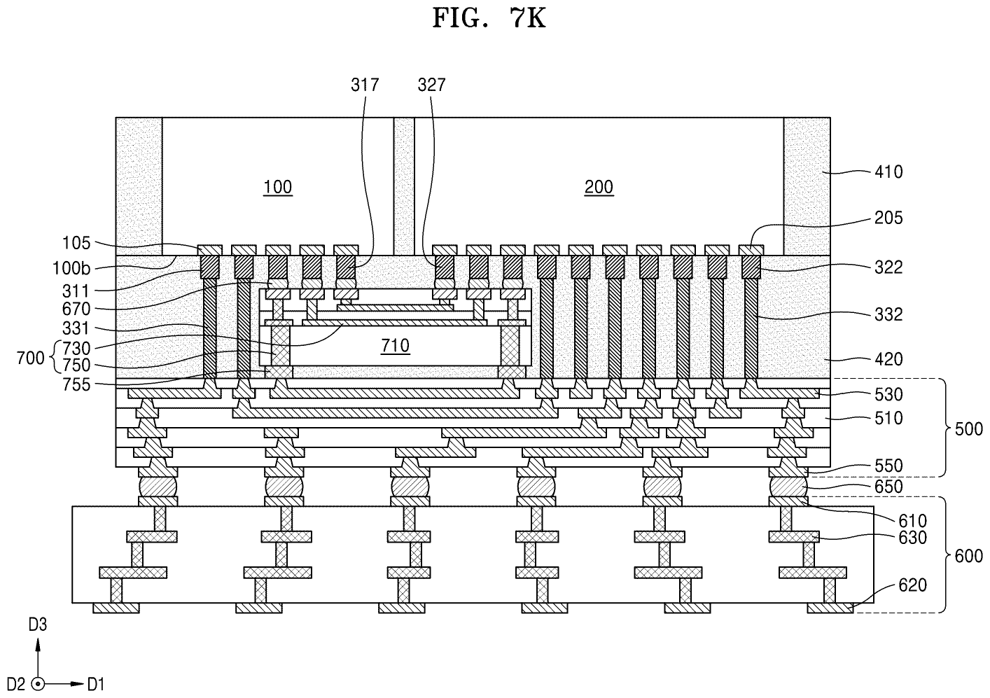

FIGS. 7A to 7K are diagrams for describing a process of manufacturing a semiconductor package, according to some embodiments. Also, some descriptions redundant with those provided above may be omitted herein in the interest of brevity. In some processes, the semiconductor device and the second semiconductor chip may be turned over so that the top surface of the semiconductor device and the top surface of the second semiconductor chip face downward. However, for uniformity, the top surface of the semiconductor device and the top surface of the second semiconductor chip are illustrated as facing upward. Some processes may correspond to FIGS. 7D to 7J, which will be described below, but the present disclosure is not limited thereto.

Referring to FIG. 7A, a semiconductor device 100 including first upper posts 311 and 317 may be prepared. The first upper posts 311 and 317 may be formed on bottom surfaces of first lower pads 105 of the semiconductor device 100. The first upper posts 311 and 317 may include a first upper connection post 311 and a first upper bridge post 317. The first upper bridge post 317 may be formed through a single process with the first upper connection post 311. The height of the first upper bridge post 317 may be substantially equal to the height H1 of the first upper connection post 311, and the material of the first upper bridge post 317 may be substantially the same as the material of the first upper connection post 311. The height H1 of the first upper connection post 311 may be, for example, about 5 μm to about 10 μm. The height of the first upper bridge post 317 may be, for example, about 5 μm to about 10 μm.

A second semiconductor chip 200 including second upper posts 322 and 327 may be prepared. The second upper posts 322 and 327 may be formed on bottom surfaces of chip pads 205 of the second semiconductor chip 200. The second upper posts 322 and 327 may include a second upper connection post 322 and a second upper bridge post 327. The second upper bridge post 327 may be formed through a single process with the second upper connection post 322. The height of the second upper bridge post 327 may be substantially equal to the height H2 of the second upper connection post 322, and the material of the second upper bridge post 327 may be substantially the same as the material of the second upper connection post 322. The height H2 of the second upper connection post 322 and the height of the second upper bridge post 327 may each be, for example, about 5 μm to about 10 μm.

A carrier substrate 900 may be prepared. The carrier substrate 900 may be a temporary substrate. A carrier adhesive layer 990 may be attached to the top surface of the carrier substrate 900. The carrier adhesive layer 990 may include an insulating polymer, but the present disclosure is not limited thereto.

The semiconductor device 100 and the second semiconductor chip 200 may be on the carrier adhesive layer 990. The semiconductor device 100 and the second semiconductor chip 200 may be attached to the carrier substrate 900 by using the carrier adhesive layer 990. In this case, the bottom surface 100b of the semiconductor device 100 and the bottom surface 200b of the second semiconductor chip 200 may be in physical contact with the carrier adhesive layer 990. The carrier adhesive layer 990 may be relatively soft, so that the first upper posts 311 and 317 and the second upper posts 322 and 327 may be inserted into the carrier adhesive layer 990. Accordingly, the first upper posts 311 and 317 and the second upper posts 322 and 327 may be provided in the carrier adhesive layer 990. The top surface of the carrier adhesive layer 990 may be provided at a higher level than the bottom surfaces of the first upper posts 311 and 317 and the bottom surfaces of the second upper posts 322 and 327. The thickness of the carrier adhesive layer 990 may be greater than the height H1 of the first upper connection post 311, the height of the first upper bridge post 317, the height H2 of the second upper connection post 322, and the height of the second upper bridge post 327. Accordingly, the bottom surfaces of the first upper posts 311 and 317 and the bottom surfaces of the second upper posts 322 and 327 may be spaced apart from the carrier substrate 900.

Referring to FIG. 7B, the first molding layer 410 may be formed on the carrier adhesive layer 990 and cover the sidewalls of the semiconductor device 100 and the sidewalls of the second semiconductor chip 200. The first molding layer 410 may expose the top surface of the semiconductor device 100 and the top surface of the second semiconductor chip 200, but the present disclosure is not limited thereto. The bottom surface 410b of the first molding layer 410 may be in direct contact with the top surface of the carrier adhesive layer 990. Accordingly, the bottom surface 410b of the first molding layer 410 may be coplanar with the bottom surface 100b of the semiconductor device 100 and the bottom surface 200b of the second semiconductor chip 200.

Because the first upper posts 311 and 317 are provided in the carrier adhesive layer 990, the semiconductor device 100 may be firmly fixed to the carrier adhesive layer 990 by the first upper posts 311 and 317 in the process of forming the first molding layer 410. Because the second upper posts 322 and 327 are provided in the carrier adhesive layer 990, the second semiconductor chip 200 may be firmly fixed to the carrier adhesive layer 990 by the second upper posts 322 and 327 in the process of forming the first molding layer 410. Accordingly, unwanted movement of the semiconductor device 100 and the second semiconductor chip 200 may be prevented. The accuracy of the semiconductor package manufacturing process may be improved and the yield of the semiconductor package may be improved.

Because the height H1 of the first upper connection post 311 and the height of the first upper bridge post 317 are each 5 μm or more, the semiconductor device 100 may be fixed relatively stably to the carrier adhesive layer 990 in the process of forming the first molding layer 410. Because the height H2 of the second upper connection post 322 and the height of the second upper bridge post 327 are each 5 μm or more, the second semiconductor chip 200 may be fixed relatively stably to the carrier adhesive layer 990 in the process of forming the first molding layer 410. Accordingly, the accuracy and efficiency of the semiconductor package manufacturing process may be further improved.

Referring to FIG. 7C, the carrier adhesive layer 990 and the carrier substrate 900 may be removed to expose the bottom surface 410b of the first molding layer 410, the bottom surface 100b of the semiconductor device 100, and the bottom surface 200b of the second semiconductor chip 200. For example, the carrier adhesive layer 990 and the carrier substrate 900 may be separated from the first molding layer 410, the semiconductor device 100, and the second semiconductor chip 200. Accordingly, the first upper posts 311 and 317 and the second upper posts 322 and 327 may be exposed. For example, the bottom surfaces and sidewalls of the first upper posts 311 and 317 and the bottom surfaces and sidewalls of the second upper posts 322 and 327 may be exposed. The bottom surface 410b of the first molding layer 410 may be provided at a higher level than the bottom surfaces of the first upper posts 311 and 317 and the bottom surfaces of the second upper posts 322 and 327.

Referring to FIG. 7D, the first lower post 331 and the second lower post 332 may be respectively formed on the bottom surface of the first upper connection post 311 and the bottom surface of the second upper connection post 322. The first and second lower posts 331 and 332 may be formed by a plating process. In this case, the second lower post 332 may be formed by a single plating process with the first lower post 331. The second lower post 332 may include the same metal as the first lower post 331. The first and second lower posts 331 and 332 may include the same metal as the first and second upper connection posts 311 and 322.

The width W3 of the first lower post 331 may be less than the width W1 of the first upper connection post 311. Accordingly, even when a process error occurs in the process of forming the first lower post 331, the first lower post 331 may be prevented from being vertically misaligned with the first upper connection post 311. For example, the top surface of the first lower post 331 may be well connected to the bottom surface of the first upper connection post 311. In contrast, the width W3 of the first lower post 331 may be substantially equal to the width W1 of the first upper connection post 311.

The height H3′ of the first lower post 331 may be greater than the height H1 of the first upper connection post 311. The height H30′ of the second lower post 332 may be greater than the height H2 of the second upper connection post 322. The height H30′ of the second lower post 332 may be equal to or similar equal to the height H3′ of the first lower post 331. In contrast, the height H30′ of the second lower post 332 may be different from the height H3′ of the first lower post 331.

The width W30 of the second lower post 332 may be less than the width W2 of the second upper connection post 322. Accordingly, even when a process error occurs in the process of forming the second lower post 332, the second lower post 332 may be prevented from being vertically misaligned with the second upper connection post 322. For example, the top surface of the second lower post 332 may be well connected to the bottom surface of the second upper connection post 322. In contrast, the width W30 of the second lower post 332 may be substantially equal to the width W2 of the second upper connection post 322.

The first and second lower posts 331 and 332 may not be formed on the bottom surface of the first upper bridge post 317 and the bottom surface of the second upper bridge post 327. The first and second lower posts 331 and 332 may be spaced apart from the first and second upper bridge posts 317 and 327.

Referring to FIG. 7E, the bridge structure 700 may be on the bottom surface 100b of the semiconductor device 100 and the bottom surface 200b of the second semiconductor chip 200. For example, the bridge structure 700 may be on the bottom surface of the first upper bridge post 317 and the bottom surface of the second upper bridge post 327.

As described in the example of FIG. 1C, the bridge structure 700 may include a base substrate 710, a bridge insulating layer 720, bridge wires 730, conductive pads 715, conductive connection portions 751, and through-vias 750. In contrast, as in the example of FIGS. 2A and 2B, the bridge structure 700 may not include conductive connection portions 751 and through-vias 750. In the process of arranging the bridge structure 700, the arrangement of the bridge structure 700 may be adjusted so that the conductive pads 715 are vertically aligned with the first and second upper bridge posts 317 and 327.

Bridge solder balls 670 may be formed between the bridge structure 700 and the first and second upper bridge posts 317 and 327, so that the bridge solder balls 670 may be connected to the conductive pads 715 and the first and second upper bridge posts 317 and 327. For example, the bridge solder balls 670 may be bonded to the top surfaces of the conductive pads 715 and the bottom surfaces of the first and second upper bridge posts 317 and 327 by the reflow process of the bridge solder balls 670. Accordingly, the second semiconductor chip 200 and the semiconductor device 100 may be electrically connected to each other through the bridge structure 700.

Conductive patterns 755 may be formed on the bottom surface of the bridge structure 700 and may be connected to the through-vias 750. The forming of the conductive patterns 755 may be performed before or after arranging the bridge structure 700. The bottom surfaces of the conductive patterns 755 may be provided at a level that is the same as or different from the bottom surfaces of the first lower post 331. The bottom surfaces of the conductive patterns 755 may be provided at a level that is the same as or different from the bottom surface of the first lower post 332.

Referring to FIG. 7F, the second molding layer 420 may be formed on the bottom surface 410b of the first molding layer 410, the bottom surface 100b of the semiconductor device 100, and the bottom surface 200b of the second semiconductor chip 200 and may cover the first upper posts 311 and 317, the second upper posts 322 and 327, the first and second lower posts 331 and 332, and the bridge structure 700. For example, the second molding layer 420 may cover the sidewalls of the first upper posts 311 and 317, the sidewalls of the second upper posts 322 and 327, and the sidewalls of the first and second lower posts 331 and 332. The second molding layer 420 may further cover the bottom surface of the bridge structure 700, the bottom surfaces of the conductive patterns 755, and the bottom surfaces of the first and second lower posts 331 and 332.

The second molding layer 420 may be formed directly on the bottom surface 410b of the first molding layer 410 and may be in physical contact with the bottom surface 410b of the first molding layer 410. For example, no other components may be between the first molding layer 410 and the second molding layer 420. The forming of the second molding layer 420 may be performed by using the same EMC as that of the first molding layer 410. Accordingly, because the difference in CTE between the first molding layer 410 and the second molding layer 420 is reduced, an occurrence of warpage of the semiconductor package in the semiconductor package manufacturing process may be prevented.

The second molding layer 420 may further extend to the gap area between the bridge structure 700 and the semiconductor device 100, the gap area between the bridge structure 700 and the first molding layer 410, and the gap area between the bridge structure 700 and the second semiconductor chip 200 and may further cover the sidewalls of the first and second upper bridge posts 317 and 327 and the sidewalls of the bridge solder balls 670. In some embodiments, as described in the example of FIG. 1D, the underfill film 470 may be formed in the gap area between the bridge structure 700 and the semiconductor device 100, the gap area between the bridge structure 700 and the first molding layer 410, and the gap area between the bridge structure 700 and the second semiconductor chip 200.

Referring to FIG. 7G, a polishing process may be performed on the bottom surface of the second molding layer 420 so that the bottom surfaces of the conductive patterns 755, the bottom surface of the first lower post 331, and the bottom surface of the second lower post 332 are exposed. The polishing process may include a chemical mechanical polishing process, but the present disclosure is not limited thereto.

In the polishing process, the lower portion of the second molding layer 420 may be removed. In addition, portions of the conductive patterns 755, a portion of the first lower post 331, or a portion of the second lower post 332 may be further removed together with the second molding layer 420. The height H3 of the first lower post 331 after the polishing process may be less than or equal to the height (see H3′ of FIG. 7F) of the first lower post 331 before the polishing process. The height H30 of the second lower post 332 after the polishing process may be less than or equal to the height (see H30′ of FIG. 7F) of the second lower post 332 before the polishing process. In FIG. 7F, even when the bottom surface of the first lower post 331, the bottom surface of the second lower post 332, or the bottom surfaces of the conductive patterns 755 are provided at different levels, the bottom surfaces of the first lower post 331, the bottom surface of the second lower post 332, and the bottom surfaces of the conductive patterns 755 may be provided at substantially the same level or may be made coplanar by the polishing process. After the polishing process, the bottom surface of the second molding layer 420 may be coplanar with the bottom surface of the first lower post 331, the bottom surface of the second lower post 332, and the bottom surfaces of the conductive patterns 755.

Referring to FIG. 7H, an insulating layer 510, seed patterns 535, and redistribution patterns 530 may be formed on the bottom surface of the second molding layer 420. The forming of the insulating layer 510 may include applying a photosensitive polymer (PID) onto the bottom surface of the second molding layer 420. The insulating layer 510 may have openings. The openings may penetrate through the insulating layer 510. The openings may expose the bottom surface of the first lower post 331, the bottom surface of the second lower post 332, and the bottom surfaces of the conductive patterns 755.

The seed patterns 535 may be formed within the openings and on the bottom surface of the insulating layer 510. The redistribution patterns 530 may be formed by a plating process using the seed patterns 535 as electrodes. The plating process may include an electroplating process.

As an example, the forming of the seed patterns 535 and the redistribution patterns 530 may include forming a seed layer within the openings and on the bottom surface of the insulating layer 510, forming a resist pattern on the seed layer, performing a plating process using the seed layer as an electrode, exposing a portion of the seed layer by removing the resist pattern, and etching the exposed portion of the seed layer. The redistribution patterns 530 may be formed within the openings and on the upper portion of the resist pattern by a plating process. Each of the redistribution patterns 530 may include a via portion and a wire portion. The via portion may be formed within the corresponding opening, and the wire portion may be formed on the bottom surface of the via portion and on the bottom surface of the insulating layer 510. The seed patterns 535 may be respectively formed on the bottom surfaces of the redistribution patterns 530 by etching the seed layer.

Referring to FIG. 7I, the process of forming the insulating layer 510, the process of forming the seed patterns 535, and the process of forming the redistribution patterns 530 may be repeatedly performed. Accordingly, the stacked insulating layers 510, the stacked seed patterns 535, and the stacked redistribution patterns 530 may be formed.

Subsequently, seed pads 555 and redistribution pads 550 may be formed. The redistribution pads 550 may be formed on the bottom surface of the lowermost insulating layer 510 and within the lowermost insulating layer 510. The forming of the redistribution pads 550 may include performing an electroplating process using the seed pads 555 as electrodes. The redistribution layer 500 may be manufactured by the examples described so far. The redistribution layer 500 may include the insulating layers 510, the seed patterns 535, the redistribution patterns 530, the seed pads 555, and the redistribution pads 550.

According to some embodiments, the redistribution layer 500 may be manufactured by a chip first process. Accordingly, the number of processes of manufacturing the redistribution layer 500 may be reduced, and thus, the redistribution layer 500 may be manufactured more simply and efficiently. Because the redistribution layer 500 is manufactured by the chip first process, solder balls may not be used for the electrical connection between the semiconductor device 100 and the redistribution layer 500 and the electrical connection between the second semiconductor chip 200 and the redistribution layer 500. For example, the semiconductor device 100 may be electrically connected to the redistribution layer 500 through the first upper connection post 311 and the first lower post 331. The second semiconductor chip 200 may be electrically connected to the redistribution layer 500 through the second upper connection post 322 and the second lower post 332. The semiconductor package manufacturing process may be further simplified, and the efficiency of the semiconductor package manufacturing process may be further improved. Hereinafter, for simplification, the illustration of the seed patterns 535 and the seed pads 555 is omitted.

Referring to FIG. 7J, connection solder balls 650 may be formed on the bottom surface of the redistribution layer 500. For example, the connection solder balls 650 may be formed on the bottom surfaces of the redistribution pads 550 and may be connected to the redistribution pads 550. Although not illustrated, connection pillars may be further provided between the redistribution pads 550 and the connection solder balls 650. The connection pillars may include metal, such as copper. Accordingly, a preliminary package may be manufactured. The preliminary package may include the redistribution layer 500, the connection solder balls 650, the first and second lower posts 331, 332, the first upper posts 311 and 317, the semiconductor device 100, the second upper posts 322 and 327, the second semiconductor chip 200, the bridge structure 700, the first molding layer 410, and the second molding layer 420.

Referring to FIG. 7K, a package substrate 600 may be prepared. The package substrate 600 may include upper substrate pads 610, substrate wires 630, and lower substrate pads 620. The preliminary package may be on the package substrate 600 so that the connection solder balls 650 are vertically aligned with the upper substrate pads 610. A reflow process of the connection solder balls 650 may be performed so that the connection solder balls 650 may be bonded to the upper substrate pads 610. Accordingly, the redistribution layer 500 may be electrically connected to the package substrate 600 through the connection solder balls 650.

Referring to FIG. 1B again, a lower underfill film 460 may be formed between the package substrate 600 and the redistribution layer 500 and cover the sidewalls of the connection solder balls 650. Solder ball terminals 675 may be formed on the bottom surface of the package substrate 600 and may be connected to the lower substrate pads 620. The manufacturing of the semiconductor package 1 may be completed by the examples described so far.

While the inventive concepts of the present disclosure have been particularly shown and described with reference to some examples of embodiments thereof, it will be understood that various changes in form and details may be made therein without departing from the scope of the following claims.

1. A semiconductor package comprising:
a redistribution layer;
a first lower post on the redistribution layer;
a second lower post on the redistribution layer and spaced laterally apart from the first lower post;
a first upper connection post on the first lower post;
a second upper connection post on the second lower post;
a bridge structure on the redistribution layer and between the first lower post and the second lower post;
a semiconductor device on the first upper connection post and a first area of the bridge structure;
a semiconductor chip on the second upper connection post and a second area of the bridge structure and spaced laterally apart from the semiconductor device; and
a lower molding layer on the redistribution layer and covering sidewalls of the first and second lower posts and sidewalls of the first and second upper connection posts,
wherein the lower molding layer is in direct contact with a bottom surface of the semiconductor device and a bottom surface of the semiconductor chip.

2. The semiconductor package of claim 1, further comprising an upper molding layer covering a sidewall of the semiconductor device and a sidewall of the semiconductor chip, wherein the lower molding layer is in direct contact with a bottom surface of the upper molding layer.

3. The semiconductor package of claim 2, wherein the bottom surface of the upper molding layer is coplanar with the bottom surface of the semiconductor device and the bottom surface of the semiconductor chip.

4. The semiconductor package of claim 2, wherein the lower molding layer and the upper molding layer each include a same epoxy-based molding compound.

5. The semiconductor package of claim 2, further comprising:
a first upper bridge post between the bridge structure and the semiconductor device; and
a second upper bridge post between the bridge structure and the semiconductor chip,
wherein the upper molding layer is spaced apart from the first upper bridge post and the second upper bridge post.

6. The semiconductor package of claim 5, wherein the lower molding layer extends between the bridge structure and the semiconductor chip and between the bridge structure and the semiconductor device and covers sidewalls of the first and second upper bridge posts.

7. The semiconductor package of claim 1, wherein the bridge structure comprises:
bridge wires; and
through-vias spaced apart from the bridge wires,
wherein the semiconductor chip is electrically connected to the semiconductor device through the bridge wires, and
wherein the semiconductor chip and the semiconductor device are electrically connected to the redistribution layer through the through-vias.

8. The semiconductor package of claim 1, wherein the semiconductor device comprises:
a first lower semiconductor chip; and
a plurality of first upper semiconductor chips stacked on the first lower semiconductor chip.

9. A semiconductor package comprising:
a first semiconductor chip;
a second semiconductor chip spaced laterally apart from the first semiconductor chip;
a first upper connection post on a bottom surface of the first semiconductor chip and connected to the first semiconductor chip;
a second upper connection post on a bottom surface of the second semiconductor chip and connected to the second semiconductor chip;
a first lower post on a bottom surface of the first upper connection post;
a second lower post on a bottom surface of the second upper connection post;
a bridge structure on the bottom surface of the first semiconductor chip and the bottom surface of the second semiconductor chip and spaced laterally apart from the first and second lower posts;
a first molding layer covering sidewalls of the first and second semiconductor chips and spaced apart from the first and second upper connection posts; and
a second molding layer on a bottom surface of the first molding layer,
wherein the second molding layer covers the bridge structure, sidewalls of the first and second lower posts, and sidewalls of the first and second upper connection posts.

10. The semiconductor package of claim 9, wherein the second molding layer is in direct contact with the bottom surface of the first molding layer, the bottom surface of the first semiconductor chip, and the bottom surface of the second semiconductor chip.

11. The semiconductor package of claim 9, further comprising:
a first upper bridge post between the bridge structure and the first semiconductor chip; and
a second upper bridge post between the bridge structure and the second semiconductor chip,
wherein the second molding layer extends onto a top surface of the bridge structure and covers sidewalls of the first and second upper bridge posts.

12. The semiconductor package of claim 11, further comprising bridge solder balls respectively provided between the bridge structure and the first and second upper bridge posts,
wherein the bridge solder balls are in direct contact with bottom surfaces of the first and second upper bridge posts, and
wherein the second molding layer covers sidewalls of the bridge solder balls.

13. The semiconductor package of claim 9, further comprising a redistribution layer on a bottom surface of the second molding layer,
wherein the redistribution layer comprises:
redistribution patterns; and
seed patterns on top surfaces of the redistribution patterns, and
wherein at least one of the seed patterns is in direct contact with a bottom surface of the first lower post.

14. The semiconductor package of claim 13, further comprising conductive patterns between the redistribution layer and the bridge structure and electrically connected to the redistribution patterns,
wherein the bridge structure comprises:
a base substrate;
bridge wires on the base substrate; and
through-vias that extend through the base substrate and are electrically separated from the bridge wires, and
wherein the through-vias are electrically connected to the conductive patterns.

15. The semiconductor package of claim 14, wherein the second molding layer further extends to a gap area between the redistribution layer and the bridge structure and further covers sidewalls of the conductive patterns.

16. The semiconductor package of claim 9, wherein the first semiconductor chip comprises a first lower semiconductor chip,
wherein the semiconductor package comprises:
a plurality of first upper semiconductor chips stacked on the first lower semiconductor chip; and
an inner molding layer on a top surface of the first lower semiconductor chip and covering sidewalls of the plurality of first upper semiconductor chips, and
wherein the second semiconductor chip is a different type from the first lower semiconductor chip and the first upper semiconductor chip.

17. A semiconductor package comprising:
a package substrate comprising lower substrate pads, substrate wires, and upper substrate pads;
solder ball terminals on bottom surfaces of the lower substrate pads;
a redistribution layer on a top surface of the package substrate and comprising an insulating layer, redistribution patterns, seed patterns, and redistribution pads;
connection solder balls between the package substrate and the redistribution layer and connected to the upper substrate pads and the redistribution pads;
lower posts on a top surface of the redistribution layer and electrically connected to the redistribution patterns, the lower posts comprising a first lower post and a second lower post spaced laterally apart from each other;
a first upper connection post on the first lower post;
a second upper connection post on the second lower post;
a bridge structure on the top surface of the redistribution layer and between the first lower post and the second lower post;
a chip stack package on a top surface of the first upper connection post and a first area of the bridge structure and connected to the first upper connection post and the bridge structure, the chip stack package comprising a first lower semiconductor chip;
a second semiconductor chip on a top surface of the second upper connection post and a second area of the bridge structure and connected to the second upper connection post and the bridge structure, the second semiconductor chip spaced laterally apart from the chip stack package;
a first molding layer covering a sidewall of the chip stack package and a sidewall of the second semiconductor chip; and
a second molding layer on the top surface of the redistribution layer and covering sidewalls of the first and second lower posts and sidewalls of the first and second upper connection posts,
wherein the second molding layer is in direct contact with a bottom surface of the first molding layer, a bottom surface of the chip stack package, and a bottom surface of the second semiconductor chip.

18. The semiconductor package of claim 17, further comprising:
a first upper bridge post between the bridge structure and the chip stack package;
a second upper bridge post between the bridge structure and the second semiconductor chip; and
bridge solder balls between the bridge structure and the first upper bridge posts and between the bridge structure and the second upper bridge posts,
wherein the first molding layer is spaced apart from the first and second upper bridge posts and the bridge solder balls.

19. The semiconductor package of claim 18, wherein a height of the first upper connection post is about 5 μm to about 10 μm,
wherein a height of the first upper bridge post is about 5 μm to about 10 μm,
wherein a height of the second upper connection post is about 5 μm to about 10 μm, and
wherein a height of the second upper bridge post is about 5 μm to about 10 μm.

20. The semiconductor package of claim 17, wherein a bottom surface of the bridge structure is spaced apart from the redistribution layer, and
wherein the second molding layer extends between the bottom surface of the bridge structure and the redistribution layer and covers the bottom surface of the bridge structure.

21.-30. (canceled)
